(19) United States
(12) Patent Application Publication
(10) Pub. No.: US 2025/0107079 A1
(43) Pub. Date: Mar. 27, 2025

(54) THREE-DIMENSIONAL MEMORY DEVICE WITH ISOLATION TRENCH FILL STRUCTURE HAVING LATERALLY-UNDULATING SIDEWALLS AND METHOD OF MAKING THE SAME

(71) Applicant: WESTERN DIGITAL TECHNOLOGIES, INC.,, SAN JOSE, CA (US)

(72) Inventors: Fei ZHOU, San Jose, CA (US); Fumitaka AMANO, Yokkaichi (JP); Rahul SHARANGPANI, Fremont, CA (US); Senaka KANAKAMEDALA, San Jose, CA (US)

(21) Appl. No.: 18/471,896

(22) Filed: Sep. 21, 2023

(51) Int. Cl. H10B 43/27; G11C 16/04; H01L 23/522; H01L 23/528; H10B 43/10; H10B 43/35; H10B 43/40

(52) U.S. Cl. CPC H10B 43/27; G11C 16/0483; H01L 23/5226; H01L 23/5283; H10B 43/10; H10B 43/35; H10B 43/40

(57) ABSTRACT

A three-dimensional memory device includes: a pair of alternating stacks of insulating layers and electrically conductive layers, the pair of alternating stacks being laterally spaced from each other by a lateral isolation trench that generally extends along a first horizontal direction; memory openings vertically extending through a respective one of the pair of alternating stacks; memory opening fill structures located in a respective one of the memory openings; and a lateral isolation trench fill structure including a peripheral spacer and a conductive fill structure, wherein a first vertical cross-sectional view of the lateral isolation trench fill structure in a first vertical plane includes: an outer periphery of the peripheral spacer which includes a horizontal top surface segment located in a first horizontal plane; and an inner periphery of the peripheral spacer that is vertically spaced from, and located entirely below, the first horizontal plane.

### FIELD

The present disclosure relates generally to the field of semiconductor devices, and particularly to three-dimensional memory devices including isolation trench fill structure having laterally-undulating sidewalls and methods for manufacturing the same.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a three-dimensional memory device is provided, which comprises: a pair of alternating stacks of insulating layers and electrically conductive layers, the pair of alternating stacks being laterally spaced from each other by a lateral isolation trench that generally extends along a first horizontal direction; memory openings vertically extending through a respective one of the pair of alternating stacks; memory opening fill structures located in a respective one of the memory openings and comprising a respective vertical semiconductor channel and a respective vertical stack of memory elements located at levels of the electrically conductive layers; and a lateral isolation trench fill structure located in the lateral isolation trench and comprising a peripheral spacer and a conductive fill structure. The lateral isolation trench fill structure has a width modulation at levels of both the insulating layers and the electrically conductive layers along a second horizontal direction that is perpendicular to the first horizontal direction as a function of a lateral distance along the first horizontal direction.

According to another aspect of the present disclosure, a method of forming a three-dimensional memory device is provided. The method comprises: forming a vertically alternating sequence of continuous insulating layers and continuous sacrificial material layers over a substrate; forming memory openings through the vertically alternating sequence; forming memory opening fill structures in the memory openings, wherein each of the memory opening fill structures comprises a respective vertical semiconductor channel and a respective vertical stack of memory elements; forming a lateral isolation trench through the vertically alternating sequence, wherein the lateral isolation trench has a width modulation at levels of both the insulating layers and the sacrificial material layers along a second horizontal direction that is perpendicular to a first horizontal direction as a function of a lateral distance along the first horizontal direction; replacing remaining portions of the continuous sacrificial material layers with electrically conductive layers to form a pair of alternating stacks of insulating layers and electrically conductive layers on opposing sides of the lateral isolation trench; and forming a lateral isolation trench fill structure in the lateral isolation trench, wherein the lateral isolation trench fill structure comprises a peripheral spacer and a conductive fill structure that is formed in the peripheral spacer.

### BRIEF DESCRIPTION OF THE DRAWINGS

FIG. 1 is a schematic vertical cross-sectional view of a first exemplary structure for forming a memory die after formation of an alternating stack of insulating layers and sacrificial material layers over a carrier substrate according to a first embodiment of the present disclosure.

FIG. 2 is a schematic vertical cross-sectional view of the first exemplary structure after formation of stepped surfaces and a stepped dielectric material portion according to the first embodiment of the present disclosure.

FIG. 3A is a schematic vertical cross-sectional view of the first exemplary structure after formation of memory openings and support openings according to the first embodiment of the present disclosure. FIG. 3B is a top-down view of the first exemplary structure of FIG. 3A. The vertical plane A-A′ is the cut plane of the vertical cross-sectional view of FIG. 3A.

FIG. 4 is a vertical cross-sectional view of the first exemplary structure after formation of sacrificial opening fill structures according to the first embodiment of the present disclosure.

FIG. 5 is a vertical cross-sectional view of the first exemplary structure after replacement of sacrificial support opening fill structures with support pillar structures according to the first embodiment of the present disclosure.

FIG. 6 is a vertical cross-sectional view of the first exemplary structure after removal of the sacrificial memory opening fill structures from the memory openings according to the first embodiment of the present disclosure.

FIGS. 7A-7D are sequential vertical cross-sectional views of a memory opening during formation of a memory opening fill structure according to the first embodiment of the present disclosure.

FIG. 8A is a vertical cross-sectional view of the first exemplary structure after formation of memory opening fill structures according to the first embodiment of the present disclosure. FIG. 8B is a top-down view of the first exemplary structure of FIG. 8A. The vertical plane A-A′ is the cut plane of the vertical cross-sectional view of FIG. 8A.

FIG. 9A is a vertical cross-sectional view of the first exemplary structure after formation of lateral isolation trenches according to the first embodiment of the present disclosure. FIG. 9B is a top-down view of the first exemplary structure of FIG. 9A.

FIG. 10A is a vertical cross-sectional view of the first exemplary structure after formation of laterally-extending cavities according to the first embodiment of the present disclosure.

FIG. 10B is a vertical cross-sectional view of a region around a memory opening of the first exemplary structure of FIG. 10A.

FIGS. 11, 12 and 13 are sequential vertical cross-sectional views of a region around a memory opening during formation of electrically conductive layers according to the first embodiment of the present disclosure.

FIG. 14 is a vertical cross-sectional view of the first exemplary structure after formation of electrically conductive layers according to the first embodiment of the present disclosure.

FIG. 15A is a vertical cross-sectional view of the first exemplary structure after formation of peripheral spacers in the lateral isolation trenches according to the first embodiment of the present disclosure. FIG. 15B is a top-down view of the first exemplary structure of FIG. 15A. The vertical plane A-A′ is the cut plane of the vertical cross-sectional view of FIG. 15A. FIG. 15C is a vertical cross-sectional view of the first exemplary structure along the vertical plane C-C′ of FIG. 15B. FIG. 15D is a vertical cross-sectional view of the first exemplary structure along the vertical plane D-D′ of FIG. 15B.

FIG. 16A is a vertical cross-sectional view of the first exemplary structure after formation of conductive fill structures in the lateral isolation trenches according to the first embodiment of the present disclosure. FIG. 16B is a top-down view of the first exemplary structure of FIG. 16A. The vertical plane A-A′ is the cut plane of the vertical cross-sectional view of FIG. 16A. FIG. 16C is a vertical cross-sectional view of the first exemplary structure along the vertical plane C-C′ of FIG. 16B. FIG. 16D is a vertical cross-sectional view of the first exemplary structure along the vertical plane D-D′ of FIG. 16B.

FIG. 17A is a vertical cross-sectional view of the first exemplary structure after formation of contact via structures according to the first embodiment of the present disclosure. FIG. 17B is a top-down view of the first exemplary structure of FIG. 17A. The vertical plane A-A′ is the cut plane of the vertical cross-sectional view of FIG. 17A.

FIG. 18A is a vertical cross-sectional view of the first exemplary structure after formation of bit lines and bit-line-level metal lines according to the first embodiment of the present disclosure. FIG. 18B is a top-down view of the first exemplary structure of FIG. 18A. The vertical plane A-A′ is the cut plane of the vertical cross-sectional view of FIG. 18A.

FIG. 19 is a vertical cross-sectional view of the first exemplary structure after formation of a memory die according to the first embodiment of the present disclosure.

FIG. 20 is a vertical cross-sectional view of a logic die according to the first embodiment of the present disclosure.

FIG. 21 is a vertical cross-sectional view of the first exemplary structure after formation of a bonded assembly of the memory die and the logic die according to the first embodiment of the present disclosure.

FIG. 22 is a vertical cross-sectional view of the first exemplary structure after removal of a carrier substrate from the memory die according to the first embodiment of the present disclosure.

FIG. 23 is a vertical cross-sectional view of the first exemplary structure after removal of the bottommost insulating layer according to the first embodiment of the present disclosure.

FIG. 24 is a vertical cross-sectional view of the first exemplary structure after removal of bottom portions of the memory films according to the first embodiment of the present disclosure.

FIG. 25 is a vertical cross-sectional view of the first exemplary structure after formation of a source layer, a backside dielectric layer, and backside contact pads according to the first embodiment of the present disclosure.

FIG. 26 is a vertical cross-sectional view of an alternative configuration of the first exemplary structure according to the first embodiment of the present disclosure.

FIG. 27 is a schematic vertical cross-sectional view of a second exemplary structure for forming a memory die after formation of an alternating stack of insulating layers and sacrificial material layers over a substrate according to a second embodiment of the present disclosure.

FIG. 28 is a schematic vertical cross-sectional view of the second exemplary structure after formation of stepped surfaces and a stepped dielectric material portion according to the second embodiment of the present disclosure.

FIG. 29A is a schematic vertical cross-sectional view of the second exemplary structure after formation of memory openings and support openings according to the second embodiment of the present disclosure. FIG. 29B is a top-down view of the second exemplary structure of FIG. 29A. The vertical plane A-A′ is the cut plane of the vertical cross-sectional view of FIG. 29A.

FIG. 30 is a vertical cross-sectional view of the second exemplary structure after formation of sacrificial opening fill structures according to the second embodiment of the present disclosure.

FIG. 31A is a vertical cross-sectional view of the second exemplary structure after formation of lateral isolation trenches according to the second embodiment of the present disclosure. FIG. 31B is a top-down view of the second exemplary structure of FIG. 31A. The vertical plane A-A′ is the cut plane of the vertical cross-sectional view of FIG. 31A.

FIG. 32 is a vertical cross-sectional view of the exemplary structure after formation of laterally-extending cavities according to the second embodiment of the present disclosure.

FIG. 33 is a vertical cross-sectional view of the second exemplary structure after formation of electrically conductive layers according to the second embodiment of the present disclosure.

FIG. 34A is a vertical cross-sectional view of the second exemplary structure after removal of the sacrificial opening fill structures according to the second embodiment of the present disclosure. FIG. 34B is a top-down view of the second exemplary structure of FIG. 34A. The vertical plane A-A′ is the cut plane of the vertical cross-sectional view of FIG. 34A. FIG. 34C is a vertical cross-sectional view of the second exemplary structure along the vertical plane C-C′ of FIG. 34B. FIG. 34D is a vertical cross-sectional view of the second exemplary structure along the vertical plane D-D′ of FIG. 34B.

FIG. 35A is a vertical cross-sectional view of a region around a memory opening and a lateral isolation trench of the second exemplary structure after deposition of a blocking dielectric layer, a memory material layer, a dielectric liner, a semiconductor channel material layer, and a dielectric core layer in the memory openings, support openings, and the lateral isolation trenches according to the second embodiment of the present disclosure. FIG. 15B is another vertical cross-sectional view of the second exemplary structure of FIG. 15B.

FIG. 36A is a vertical cross-sectional view of a region around a memory opening and a lateral isolation trench of the second exemplary structure after deposition of a conductive fill material layer in the lateral isolation trenches according to the second embodiment of the present disclosure. FIG. 36B is another vertical cross-sectional view of the second exemplary structure of FIG. 36B.

FIG. 37A is a vertical cross-sectional view of a region around a memory opening and a lateral isolation trench of the second exemplary structure after performing a planarization process according to the second embodiment of the present disclosure. FIG. 37B is another vertical cross-sectional view of the second exemplary structure of FIG. 37B.

FIG. 38A is a vertical cross-sectional view of a region around a memory opening and a lateral isolation trench of the second exemplary structure after performing a recess etch process according to the second embodiment of the present disclosure. FIG. 38B is another vertical cross-sectional view of the second exemplary structure of FIG. 38B.

FIG. 39A is a vertical cross-sectional view of the second exemplary structure after formation of drain structures according to the second embodiment of the present disclosure.

FIG. 39B is a top-down view of the second exemplary structure of FIG. 39A. The vertical plane A-A′ is the cut plane of the vertical cross-sectional view of FIG. 39A. FIG. 39C is a vertical cross-sectional view of the second exemplary structure along the vertical plane C-C′ of FIG. 39B. FIG. 39D is a vertical cross-sectional view of the second exemplary structure along the vertical plane D-D′ of FIG. 39B.

FIG. 40A is a vertical cross-sectional view of the second exemplary structure after formation of contact via structures according to the second embodiment of the present disclosure. FIG. 40B is a top-down view of the second exemplary structure of FIG. 40A. The vertical plane A-A′ is the cut plane of the vertical cross-sectional view of FIG. 40A.

FIG. 41 is a vertical cross-sectional view of the second exemplary structure after formation of a memory die according to the second embodiment of the present disclosure.

FIG. 42 is a vertical cross-sectional view of the second exemplary structure after formation of a bonded assembly of the memory die and the logic die according to the second embodiment of the present disclosure.

FIG. 43 is a vertical cross-sectional view of the second exemplary structure after removal of a carrier substrate from the memory die according to the second embodiment of the present disclosure.

FIG. 44 is a vertical cross-sectional view of the second exemplary structure after formation of a source layer, a backside dielectric layer, and backside contact pads according to the second embodiment of the present disclosure.

FIG. 45 is a vertical cross-sectional view of an alternative configuration of the second exemplary structure according to the second embodiment of the present disclosure.

### DETAILED DESCRIPTION

As discussed above, the present disclosure is directed to three-dimensional memory devices including isolation trench fill structure having laterally-undulating sidewalls and methods for manufacturing the same, the various aspects of which are described below.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

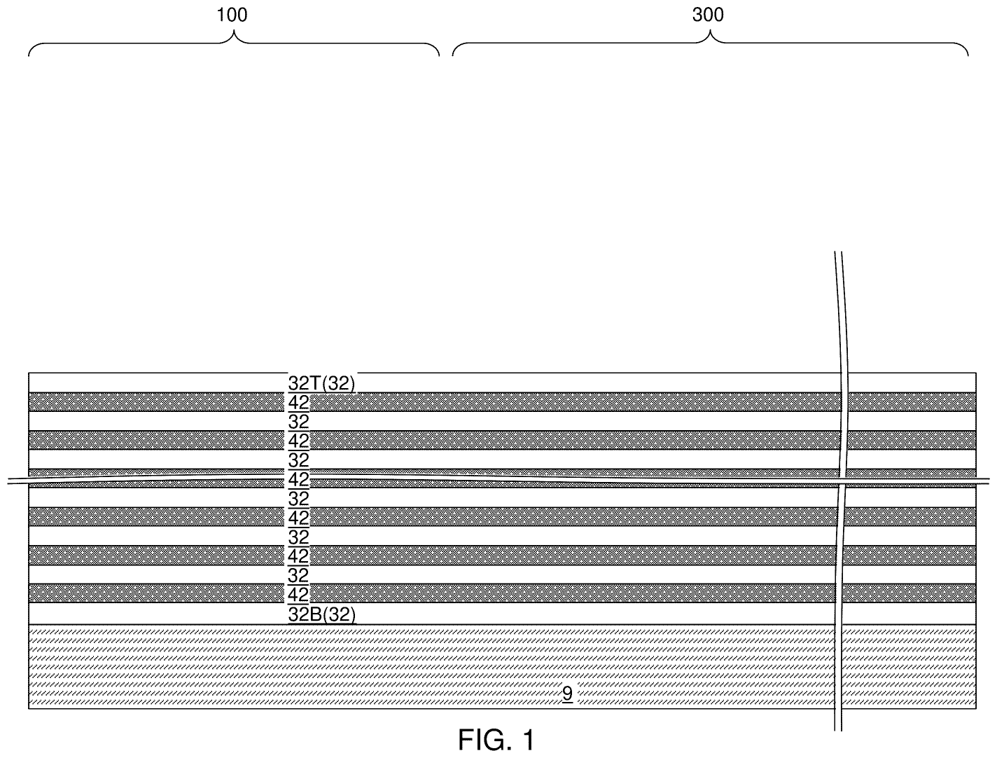

Referring to FIG. 1, a first exemplary structure according to a first embodiment of the present disclosure is illustrated. The first exemplary structure comprises a carrier substrate 9, which may be a semiconductor substrate or a conductive substrate. For example, the carrier substrate 9 may comprise a commercially available silicon wafer. Alternatively, the carrier substrate 9 may comprise any material that may be removed selective the materials of insulating layers 32 and dielectric material portions to be subsequently formed.

An alternating stack of first material layers and second material layers can be formed the carrier substrate 9. In the alternating stack, the first material layers may be insulating layers, and the second material layers may be spacer material layers. In one embodiment, the spacer material layers may comprise sacrificial material layers 42. In this case, an alternating stack (32, 42) of insulating layers 32 and sacrificial material layers 42 can be formed over the substrate 9. The insulating layers 32 comprise an insulating material such as undoped silicate glass or a doped silicate glass, and the sacrificial material layers 42 comprise a sacrificial material, such as silicon nitride or a silicon-germanium alloy. In one embodiment, the insulating layers 32 (i.e., the first material layers) may comprise silicon oxide layers, and the sacrificial material layers 42 (i.e., the second material layers) may comprise silicon nitride layers. The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 is an insulating layer 32 that is most proximal to the carrier substrate 9 is herein referred to as a bottommost insulating layer 32B. Each of the insulating layers 32 other than the topmost insulating layer 32 may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, the topmost insulating layer 32 may have a thickness of about one half of the thickness of other insulating layers 32.

The first exemplary structure comprises a memory array region 100 in which a three-dimensional array of memory elements is to be subsequently formed, and a contact region 300 in which layer contact via structures contacting word lines are to be subsequently formed. The insulating layers 32 continuously extend across the memory array region 100 and the contact region 300 without a pattern, and may be referred to as continuous insulating layers 32. The sacrificial material layers 42 continuously extend across the memory array region 100 and the contact region 300 without a pattern, and may be referred to as continuous sacrificial material layers 42. Thus, a vertically alternating sequence of continuous insulating layers 32 and continuous sacrificial material layers 42 can be formed.

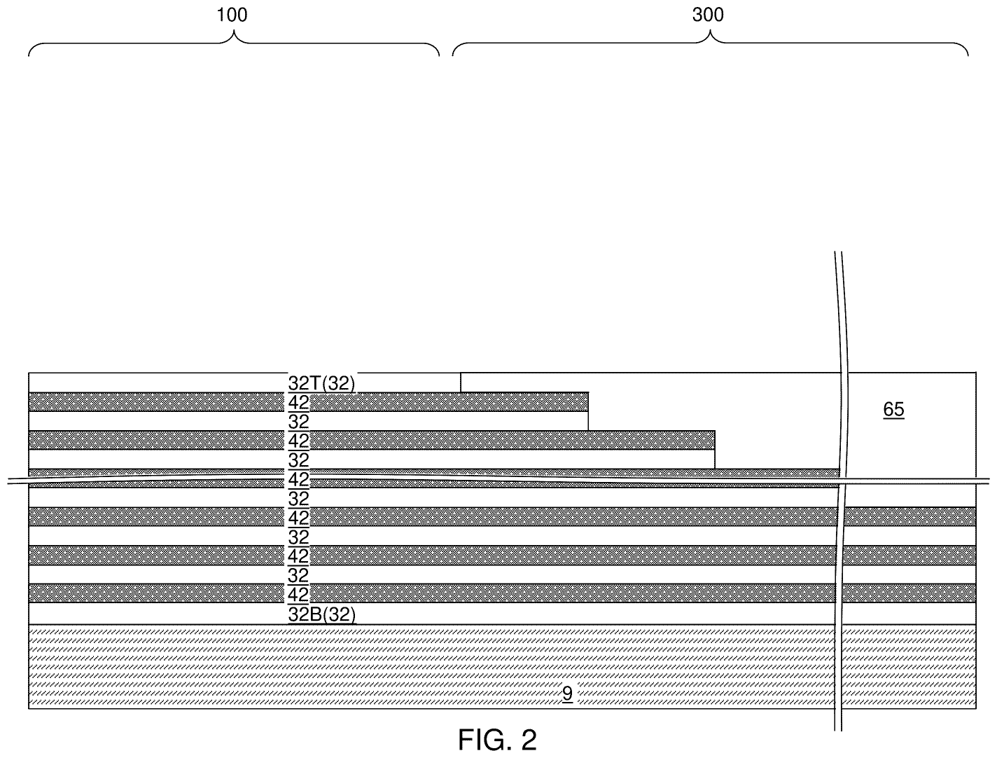

Referring to FIG. 2, stepped surfaces are formed in the contact region 300. As used herein, “stepped surfaces” refer to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A stepped cavity is formed within the volume from which portions of the alternating stack (32, 42) are removed through formation of the stepped surfaces. A “stepped cavity” refers to a cavity having stepped surfaces.

The stepped cavity can have various stepped surfaces such that the horizontal cross-sectional shape of the stepped cavity changes in steps as a function of the vertical distance from the top surface of the substrate. In one embodiment, the stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each sacrificial material layer 42 other than a topmost sacrificial material layer 42 within the alternating stack (32, 42) laterally extends farther than any overlying sacrificial material layer 42 within the alternating stack (32, 42) in the terrace region. The stepped surfaces of the alternating stack (32, 42) continuously extend from a bottommost layer within the alternating stack (32, 42) (such as the bottommost insulating layer 32B) to a topmost layer within the alternating stack (32, 42) (such as the topmost insulating layer 32T).

A stepped dielectric material portion 65 (i.e., an insulating fill material portion) can be formed in the stepped cavity by deposition of a dielectric material therein. For example, a dielectric material such as silicon oxide can be deposited in the stepped cavity. Excess portions of the deposited dielectric material can be removed from above the top surface of the topmost insulating layer 32T, for example, by chemical mechanical planarization (CMP). The remaining portion of the deposited dielectric material filling the stepped cavity constitutes the stepped dielectric material portion 65, which can be a retro-stepped dielectric material portion. As used herein, a “retro-stepped” element refers to an element that has stepped surfaces and a horizontal cross-sectional area that increases monotonically as a function of a vertical distance from a top surface of a substrate on which the element is present. If silicon oxide is employed for the stepped dielectric material portion 65, the silicon oxide of the stepped dielectric material portion 65 may, or may not, be doped with dopants such as B, P, and/or F.

Optionally, drain-select-level isolation structures (not shown) can be formed through the topmost insulating layer 32T and a subset of the sacrificial material layers 42 located at drain-select-levels. The drain-select-level isolation structures can be formed, for example, by forming drain-select-level lateral isolation trenches and filling the drain-select-level lateral isolation trenches with a dielectric material such as silicon oxide. Excess portions of the dielectric material can be removed from above the top surface of the topmost insulating layer 32T.

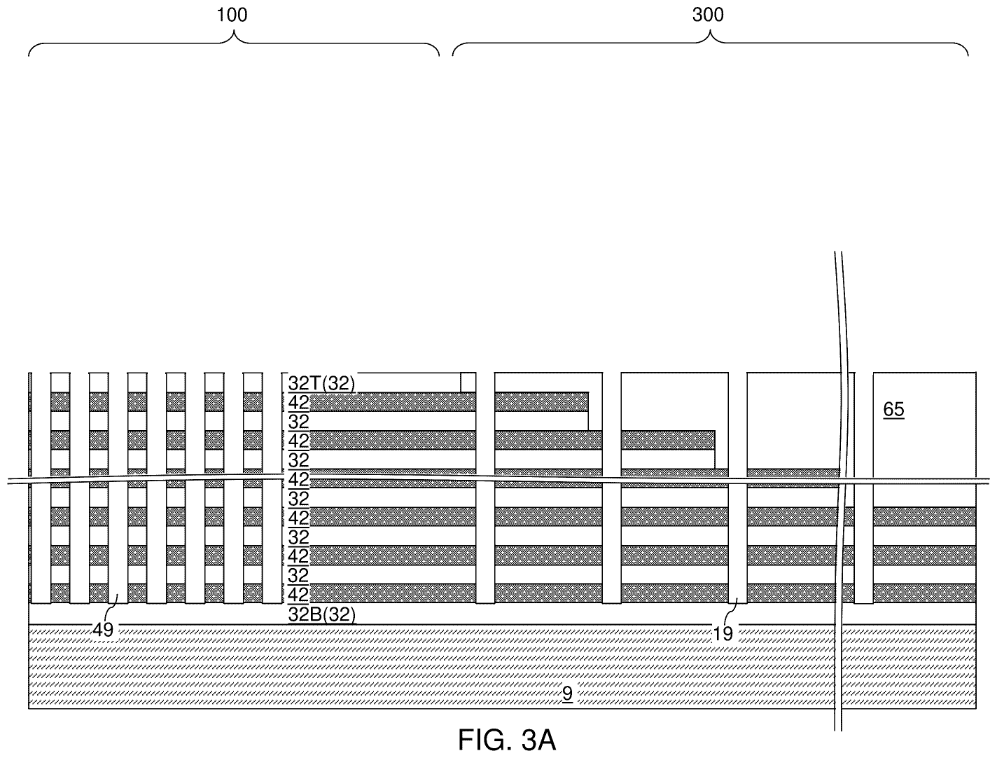

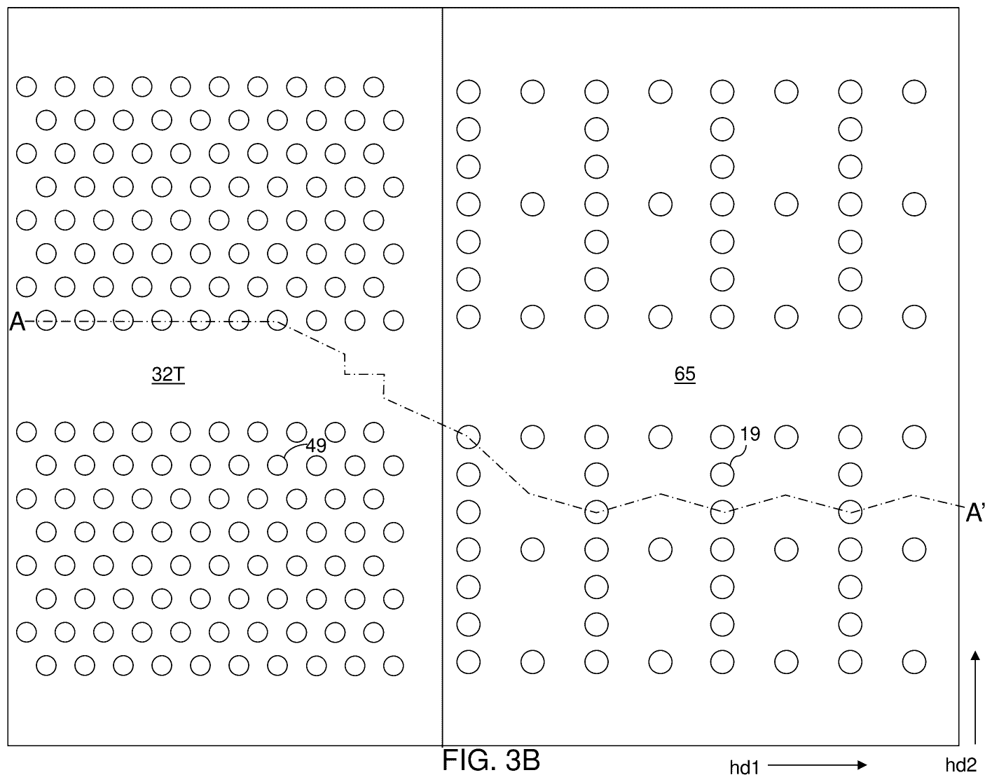

Referring to FIGS. 3A and 3B, an etch mask layer (not shown) can be formed over the alternating stack (32, 42), and can be lithographically patterned to form openings therein. An anisotropic etch process can be performed to transfer the pattern of the openings in the etch mask layer through the alternating stack (32, 42) to form memory openings 49 and support openings 19. The memory openings 49 can be formed through the alternating stack (32, 42) in the memory array region 100. Each of the memory openings 49 can vertically extend through the alternating stack (32, 42). The support openings 19 can be formed through the alternating stack (32, 42) and the stepped dielectric material portion 65 in the contact region 300. In one embodiment, the support openings 19 may have the same depth as the memory openings 49.

In one embodiment, the memory array region 100 may be laterally spaced apart from the contact region 300 along a first horizontal direction hd1. The memory openings 49 may comprise rows of memory openings 49 that are arranged along the first horizontal direction hd1 and laterally spaced apart along a second horizontal direction hd2 that is perpendicular to the first horizontal direction hd2. Multiple clusters of memory openings 49, each containing a respective two-dimensional periodic array of memory openings 49, may be formed in the memory array region 100. The clusters of memory openings 49 may be laterally spaced apart along the second horizontal direction hd2 by strip regions that are free of any opening (49, 19). Likewise, multiple clusters of support openings 19 may be formed in the contact region such that the clusters of support openings 19 may be laterally spaced apart along the second horizontal direction hd2 by the strip regions that are free of any opening (49, 19).

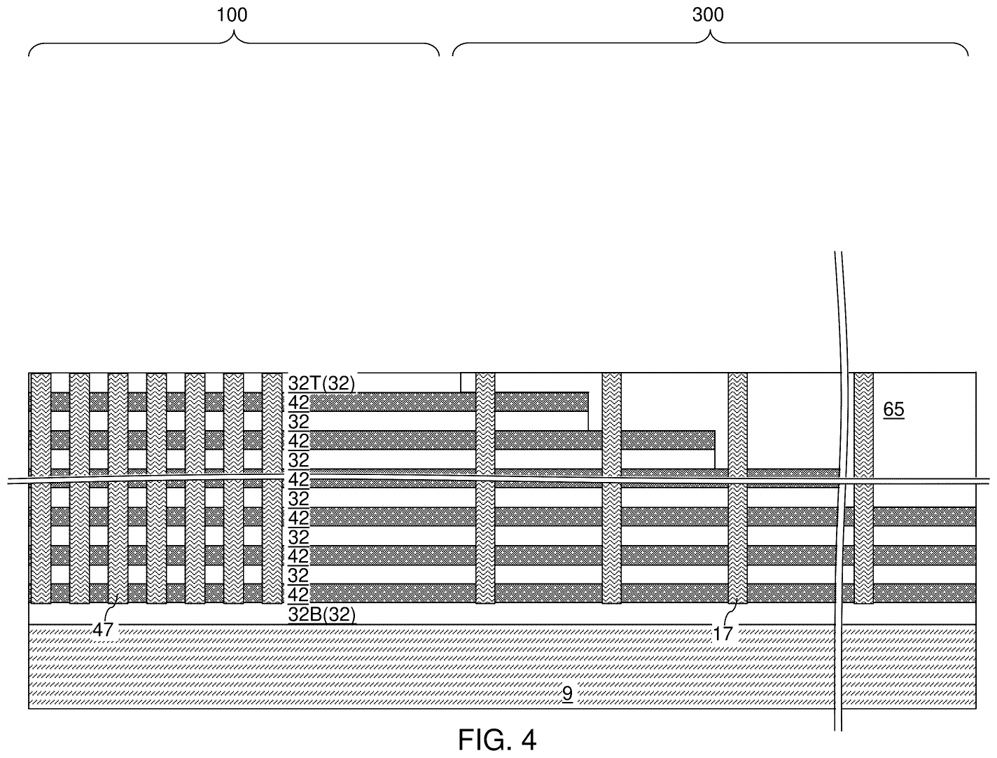

Referring to FIG. 4, a sacrificial fill material such as amorphous carbon or diamond-like carbon may be deposited in the memory openings 49 and the support openings 19 by a conformal deposition process. Excess portions of the sacrificial fill material can be removed from above the horizontal plane including the top surface of the topmost insulating layer 32T by a planarization process such as a recess etch process or a chemical mechanical polishing process. Remaining portions of the sacrificial fill material that fills the memory openings 49 constitute sacrificial memory opening fill structures 47. Remaining portions of the sacrificial fill material that fills the support openings 19 constitute sacrificial support opening fill structures 17.

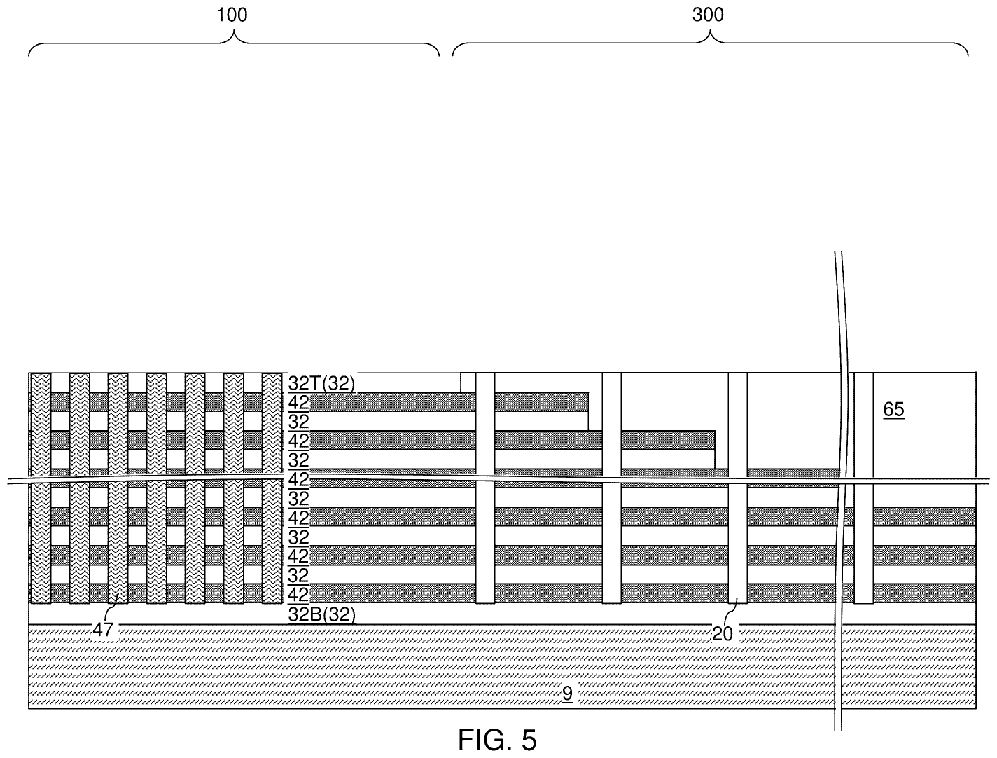

Referring to FIG. 5, a mask layer (not illustrated) can be applied over the first exemplary structure, and can be lithographically patterned to cover the memory array region 100 without covering the contact region 300. The mask layer may comprise a dielectric material such as silicon oxide or silicon nitride, and may have a thickness in a range from 5 nm to 50 nm, although lesser and greater thicknesses may also be employed. The sacrificial support opening fill structures 17 can be removed selective to the materials of the alternating stack (32, 42) (i.e., the vertically alternating sequence (32, 42)) and the substrate 9 by performing a selective removal process, such as an ashing process. Cavities are formed in the volumes of the support openings 19. A dielectric fill material, such as silicon oxide, can be deposited in the cavities. Excess portions of the dielectric fill material overlying the horizontal plane including the top surface of the stepped dielectric material portion 65 can be removed by a planarization process such as a recess etch process or a chemical mechanical polishing process. Remaining portions of the dielectric fill material filling the support openings 19 constitute support pillar structures 20. The mask layer can be subsequently removed, for example, by a selective etch process.

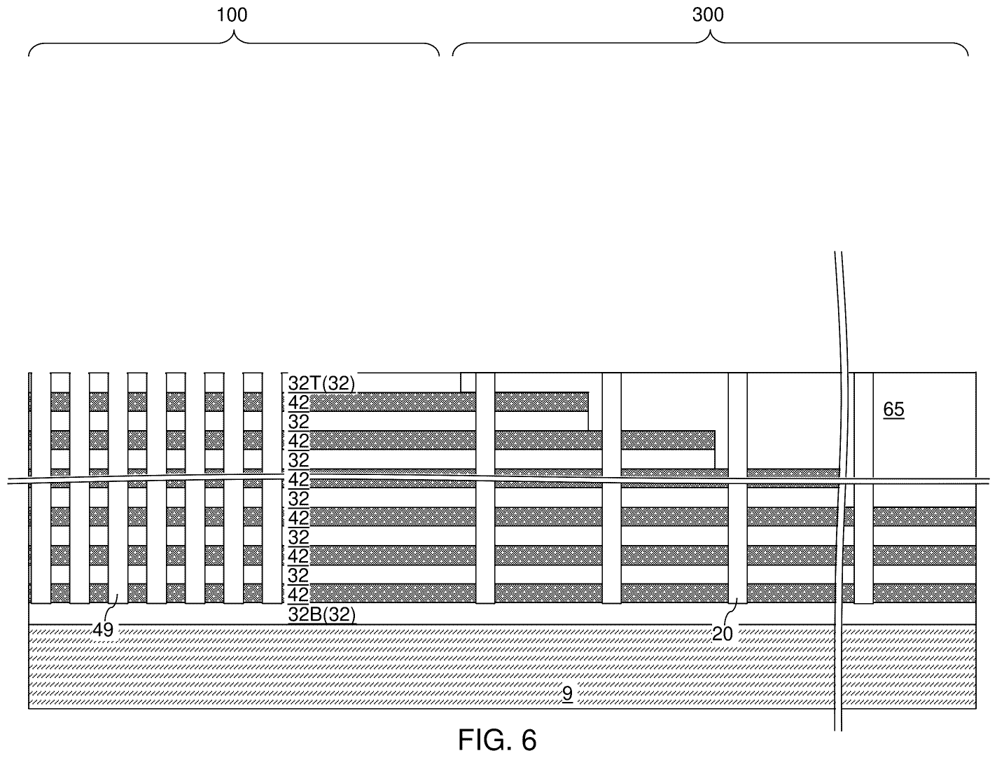

Referring to FIG. 6, the sacrificial memory opening fill structures 47 can be removed selective to the materials of the alternating stack (32, 42) (i.e., the vertically alternating sequence (32, 42)) and the substrate 9 by performing a selective removal process, such as an ashing process. Cavities are formed in the volumes of the memory openings 49.

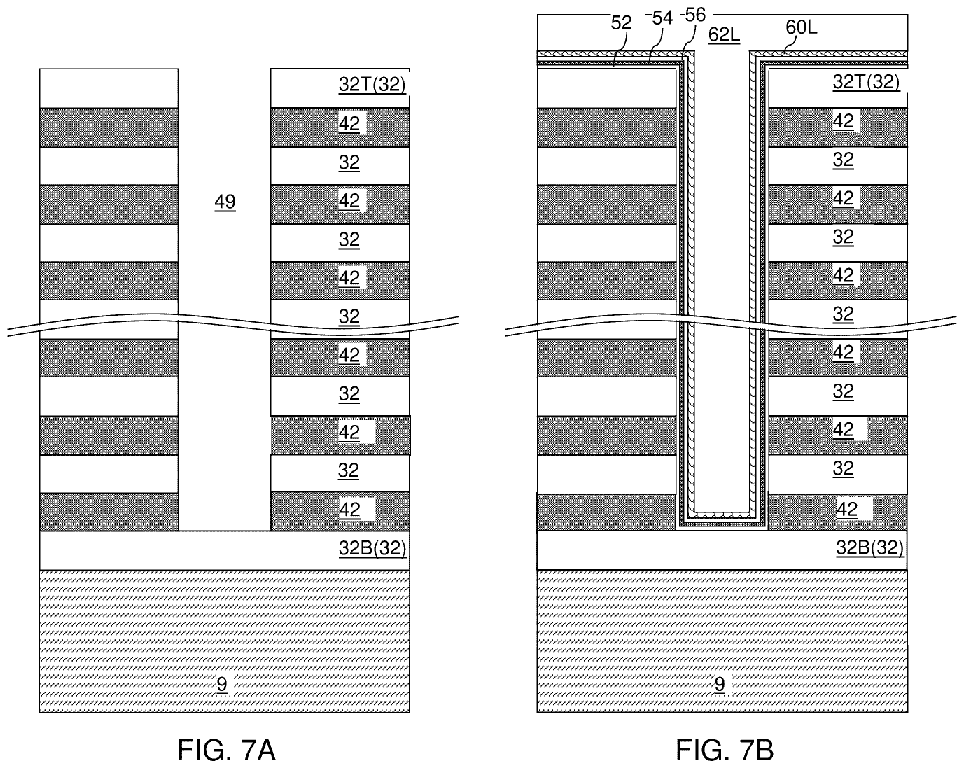

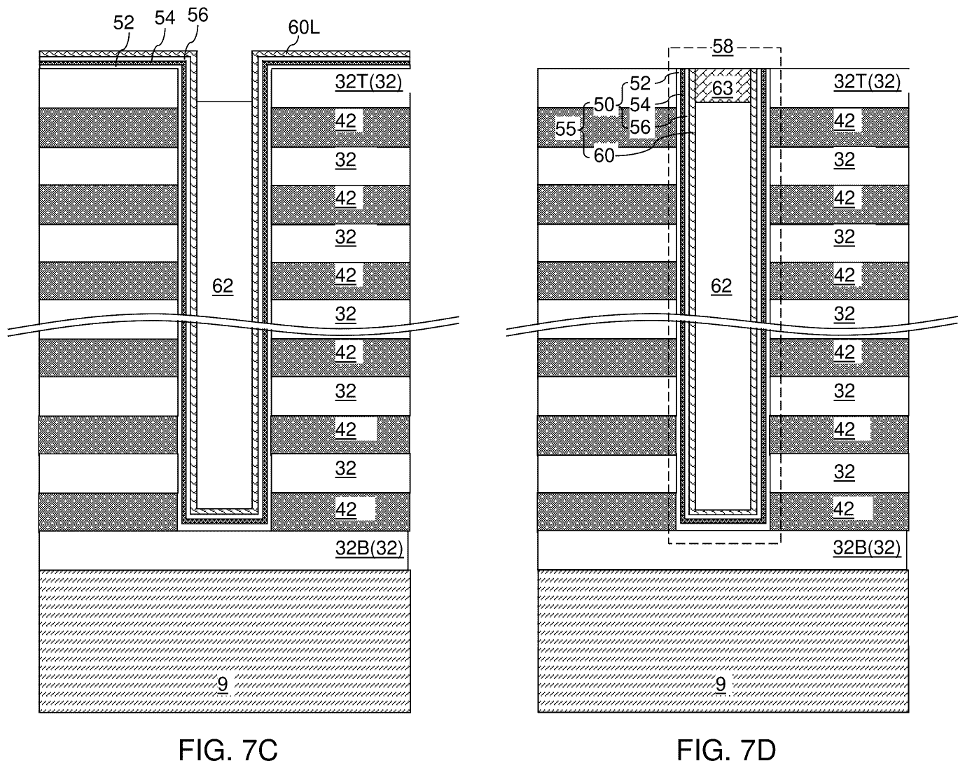

FIGS. 7A-7D are sequential vertical cross-sectional views of a memory opening 49 during formation of a memory opening fill structure 58 according to an embodiment of the present disclosure. The memory opening fill structure 58 may comprise a NAND string.

In an alternative embodiment, instead of forming the dielectric support pillar structures 20 described above, dummy memory opening fill structures may be formed in the support openings 19 at the same time and during the same process steps as the memory opening fill structures 58 are formed in the memory openings. The dummy memory opening fill structures function as support pillar structures 20 in the alternative embodiment.

Referring to FIG. 7A, a memory opening 49 is illustrated after the processing steps of FIG. 6. Referring to FIG. 7B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprise a charge storage material, the optional dielectric liner 56 may comprise a tunneling dielectric layer.

A semiconductor channel material layer 60L can be deposited over the layer stack (52, 54, 56) by performing a conformal deposition process. If the semiconductor channel material layer 60L is doped, the semiconductor channel material layer 60L may have a doping of a first conductivity type, which may be p-type or n-type. In one embodiment, the first semiconductor material comprises a first doped silicon material having a doping of the first conductivity type. In an illustrative example, the atomic concentration of dopants of the first conductivity type in the semiconductor channel material layer 60L may be in a range from 1.0×10¹³/cm³ to 3.0×10¹⁷/cm³, such as 1.0×10¹⁴/cm³ to 3.0×10¹⁶/cm³, although lesser and greater atomic concentrations may also be employed. A dielectric core layer 62L comprising a dielectric fill material can be deposited in remaining volumes of the memory openings 49 and over the alternating stack (32, 42).

Referring to FIG. 7C, the dielectric core layer 62L can be vertically recessed such that each remaining portion of the dielectric core layer 62L has a top surface at, or about, the horizontal plane including the bottom surface of the topmost insulating layers 32T. Each remaining portion of the dielectric core layer 62L constitutes a dielectric core 62.

Referring to FIG. 7D, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel material layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination of a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42, or generally speaking, at levels of spacer material layers that may be subsequently replaced at least partly with electrically conductive layers.

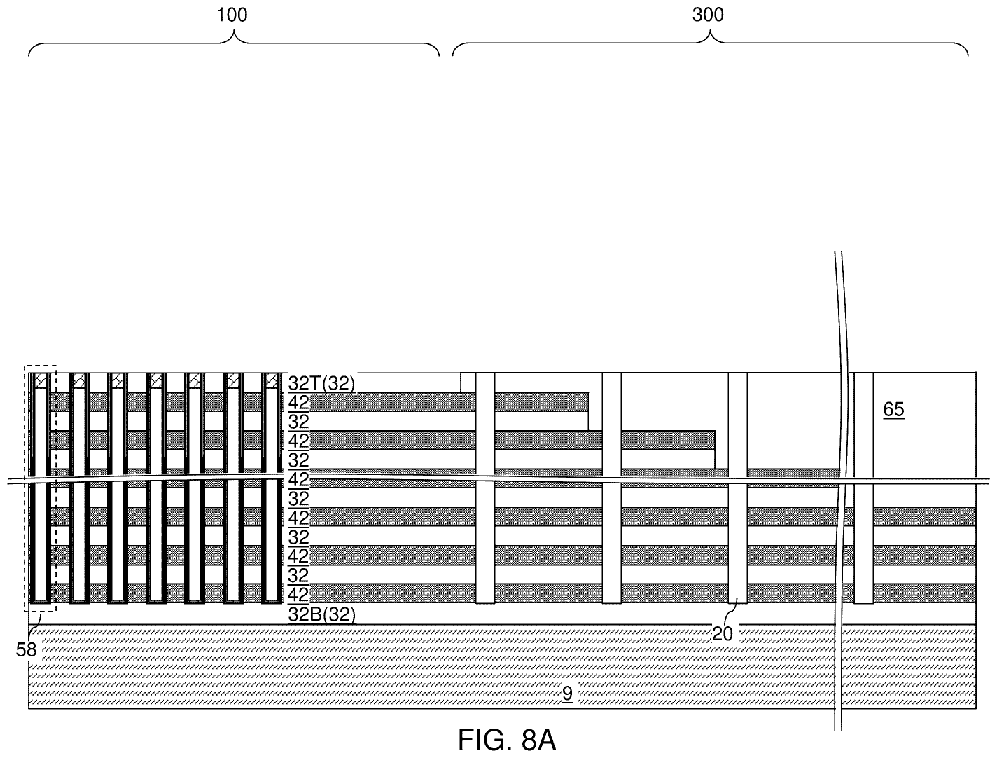

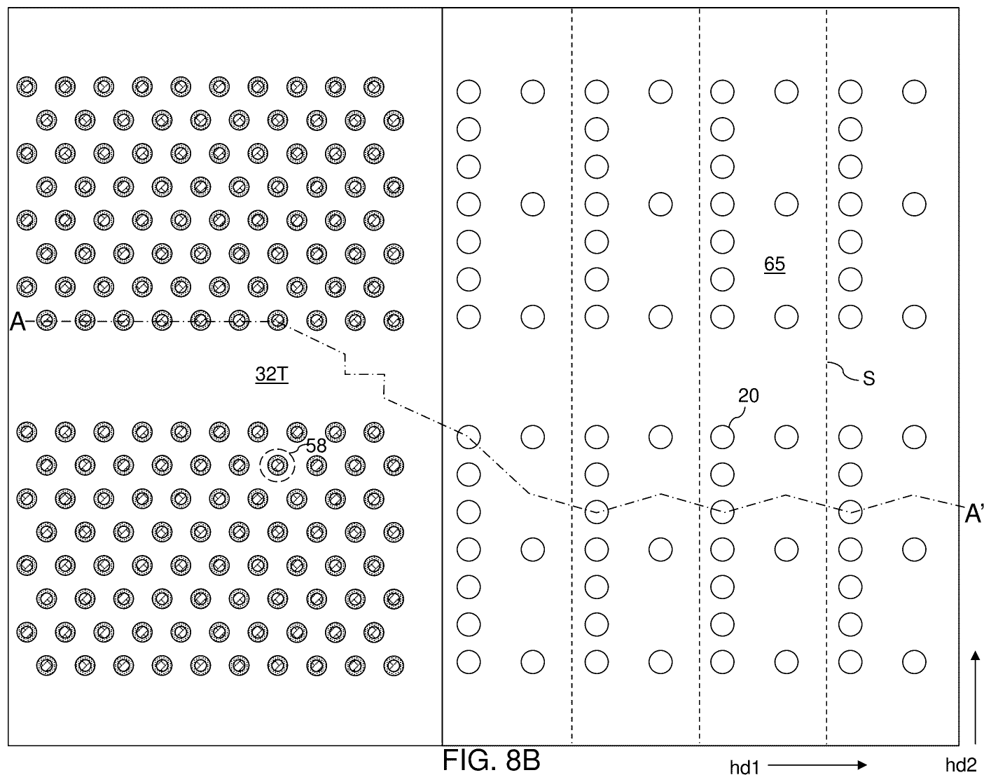

Referring to FIGS. 8A and 8B, the first exemplary structure is illustrated after formation of memory opening fill structures 58 within the memory openings 49. Each of the memory opening fill structures 58 may comprise a memory film 50 and a vertical semiconductor channel 60. Each of the memory opening fill structures 58 comprises a respective vertical stack of memory elements, which may comprise portions of a respective memory material layer 54 of the memory film 50 located at levels of the sacrificial material layers 42.

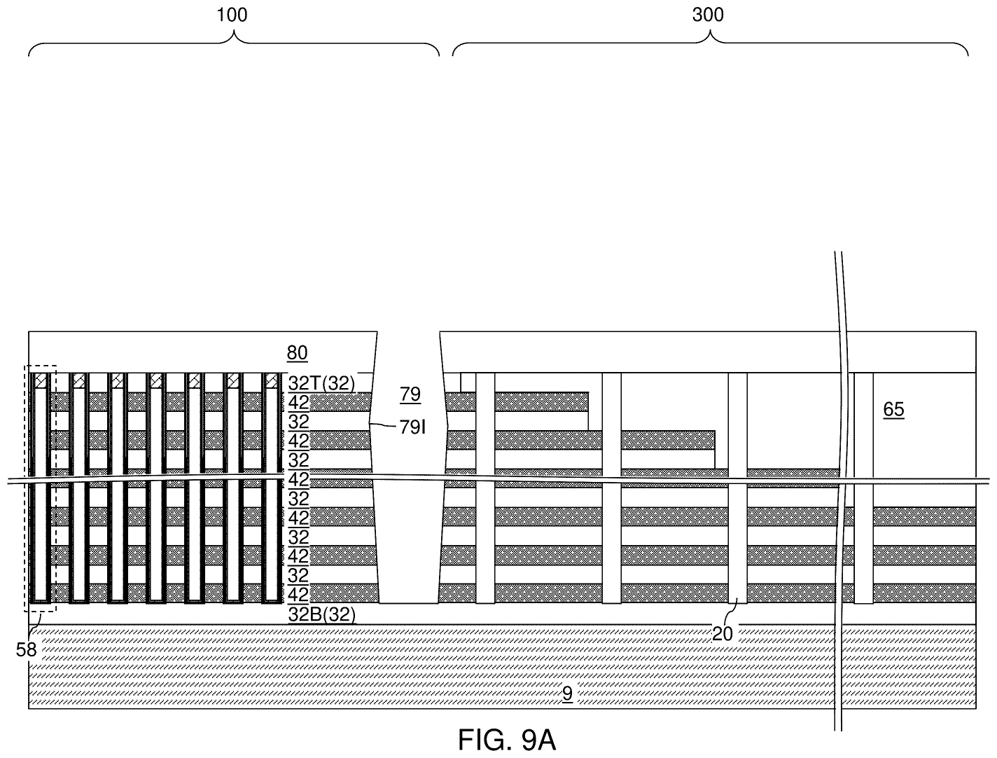

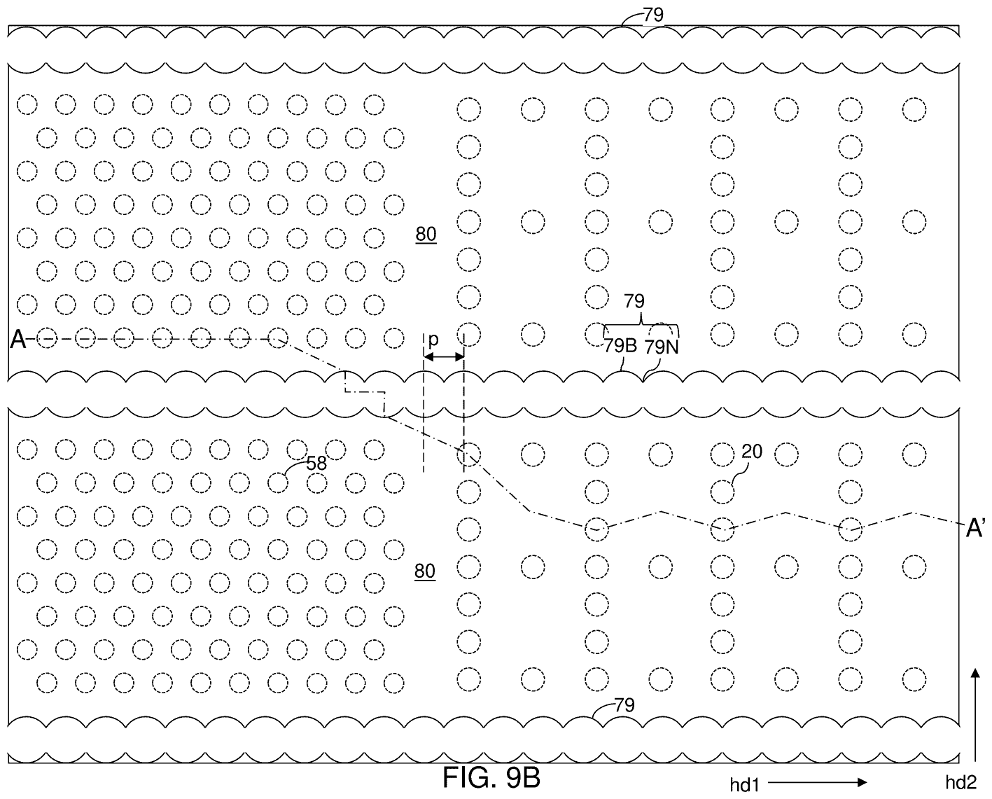

Referring to FIGS. 9A and 9B, a dielectric material such as undoped silicate glass or a doped silicate glass can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A photoresist layer (not shown) can be applied over the contact-level dielectric layer 80, and can be lithographically patterned to form various discrete openings therein. The openings in the photoresist layer overlie areas between neighboring clusters of memory opening fill structures 58 (e.g., between adjacent memory block areas).

An anisotropic etch process can be performed to transfer the pattern of the discrete openings in the photoresist layer through the contact-level dielectric layer 80, the alternating stack (32, 42) (i.e., the vertically alternating sequence (32, 42)), and the stepped dielectric material portion 65, and optionally into the substrate 9.

The discrete openings which extend through the contact-level dielectric layer 80, the alternating stack (32, 42), and the stepped dielectric material portion 65 are then expanded by at the levels of the insulating layers 32 and the sacrificial material layers 42 by performing at least one isotropic etch. In one embodiment, a sequence of two isotropic etches may be performed to expand the discrete openings. During a first isotropic etch, hydrofluoric acid is provided into the discrete openings to recess the silicon oxide insulating layers 32. During a second isotropic etch, hot phosphoric acid is provided into the discrete openings to recess the silicon nitride sacrificial material layers 42. The order of steps of the first and second isotropic etch may be reversed in an alternative embodiment.

Each of the expanded discrete openings is merged with at least one adjacent discrete opening at the levels of the insulating layers 32 and the sacrificial material layers 42 to form continuous lateral isolation trenches 79. The continuous lateral isolation trenches 79 extend through the alternating stack (32, 42) and the stepped dielectric material portion 65. The lateral isolation trenches 79 vertically extend through each layer within the alternating stack (32, 42) and optionally into an upper portion of a top portion of the substrate 9. The lateral isolation trenches 79 laterally extend along the first horizontal direction hd1 (e.g., word line direction). Each of the lateral isolation trenches 79 may comprise a respective pair of laterally-undulating lengthwise sidewalls that generally extend along the first horizontal direction hd1, have a respective width modulation along the second horizontal direction hd2, and vertically extend from at least the bottom sacrificial material layer 42 to the top surface of the contact-level dielectric layer 80. In one embodiment, the substrate 9 may be physically exposed underneath each lateral isolation trench 79.

In one embodiment, the lateral isolation trenches 79 may have a respective vertical cross-sectional profile including an inflection line 79I, at which a tapered surface segment of a continuously-extending sidewall is adjoined to a reverse-tapered surface segment of a continuously-extending sidewall. As used herein, a tapered surface segment refers to a surface segment at which a lateral dimension of a volume of an element increases with a vertical distance from an underlying substrate, and a reverse-tapered surface segment refers to a surface segment at which the lateral dimension of the volume of the element decreases with a vertical distance from the underlying substrate. Generally, the sidewall of the lateral isolation trenches 79 may optionally have gradually changing slopes, and may optionally have a bowing vertical cross-sectional profile, with the largest width being at the inflection line 79I. The lateral isolation trenches 79 may have a maximum lateral width at along the second horizontal direction hd2 at the inflection line 79I in a range from 120 nm to 500 nm, such as from 200 nm to 300 nm, although lesser and greater lateral dimensions may be employed. Each inflection line may laterally extend generally along the first horizontal direction hd1, and may have a respective periodic lateral undulation along the second horizontal direction hd2.

In summary, each lateral isolation trench 79 may comprise a pair of lengthwise sidewalls that generally extend along the first horizontal direction hd1. A vertical cross-sectional profile of the lateral isolation trench 79 in a vertical plane that is perpendicular to the first horizontal direction hd1 has a variable width that increases with a vertical distance from a horizontal plane including a bottommost surface of the vertically alternating sequence (32, 42) in a lower portion of the vertically alternating sequence (32, 42), and decreases with the vertical distance from the horizontal plane in an upper portion of the vertically alternating sequence (32, 42). In one embodiment, each lateral isolation trench 79 has a width modulation along a second horizontal direction hd2 that is perpendicular to the first horizontal direction hd1 as a function of a lateral distance along the first horizontal direction hd1.

In one embodiment shown in FIG. 9B, each lateral isolation trench 79 comprises a periodic laterally alternating sequence of neck regions 79N having a minimum width along the second horizontal direction hd2 and bulging regions 79B having a maximum width along the second horizontal direction hd2. A distance along the first horizontal direction hd1 between adjacent neck regions 79N or between adjacent bulging regions 79B comprises a pitch p. In one embodiment, each lateral isolation trench 79 comprises a pair of laterally-undulating lengthwise sidewalls, and each of the pair of laterally-undulating lengthwise sidewalls comprises a set of horizontally-convex and vertically-tapered surface segments that are adjoined to each other at edges.

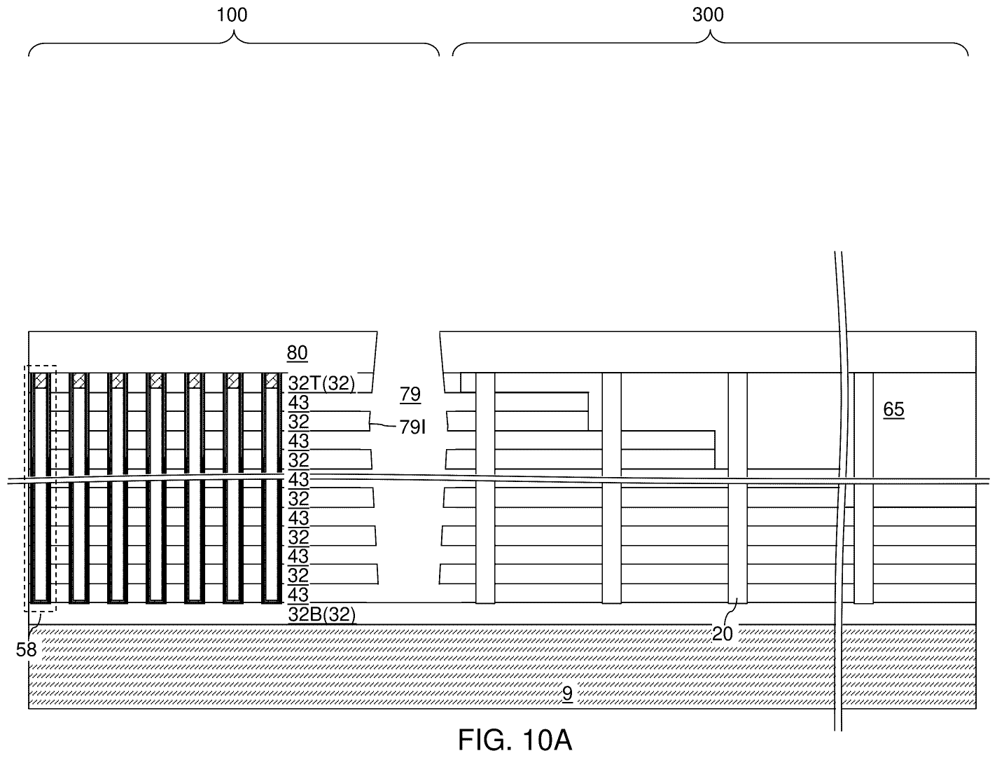

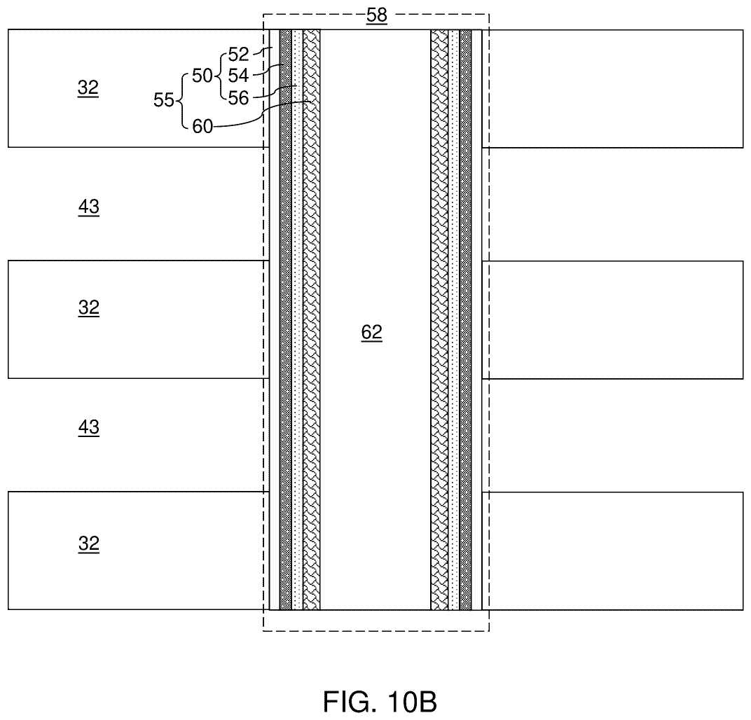

Referring to FIGS. 10A and 10B, an isotropic etch process can be performed to remove the sacrificial material layers 42 selective to the insulating layers 32, the memory opening fill structures 58, and optionally the substrate 9. Laterally-extending cavities 43 can be formed in volumes from which the sacrificial material layers 42 are removed. Sidewall surface segments of the memory opening fill structures 58 can be physically exposed to the laterally-extending cavities 43. In an illustrative example, if the sacrificial material layers 42 comprise silicon nitride, the isotropic etch process may comprise a wet etch process employing hot phosphoric acid.

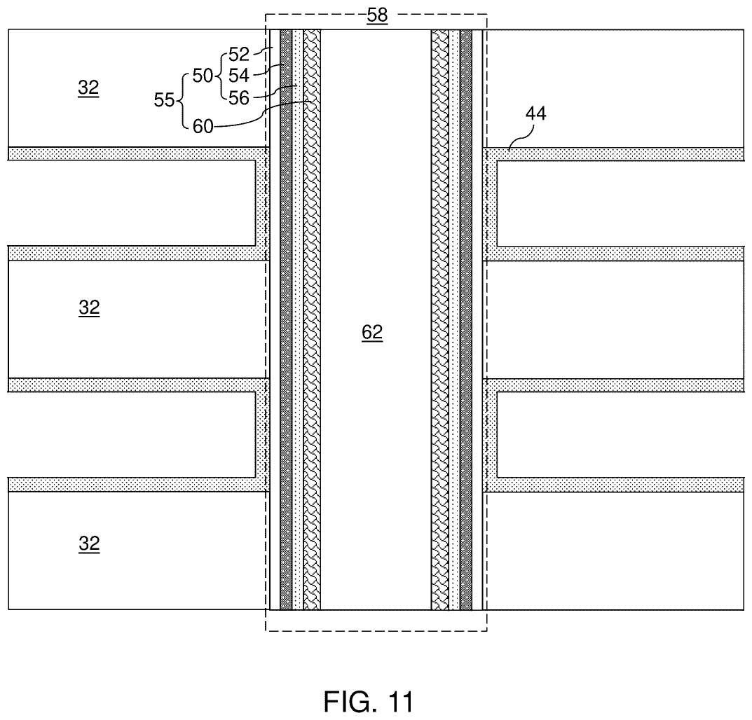

Referring to FIG. 11, an outer blocking dielectric layer 44 can be optionally formed in the laterally-extending cavities 43 by a conformal deposition process. The outer blocking dielectric layer 44 may comprise a metal oxide layer, such as aluminum oxide.

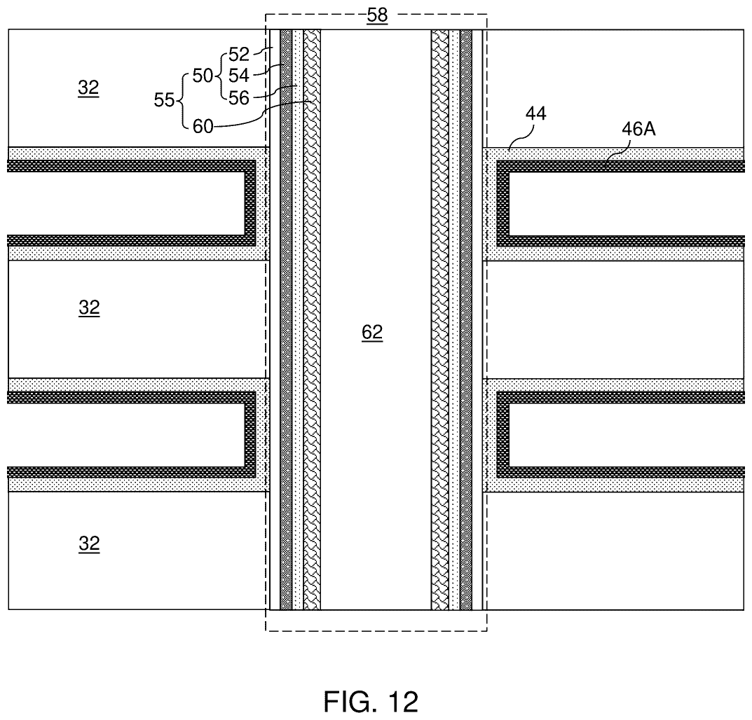

Referring to FIG. 12, a metallic barrier material can be conformally deposited in the laterally-extending cavities 43. The metallic barrier material may comprise, for example, TiN, TaN, WN, MON, TIC, TaC, WC, or a combination thereof.

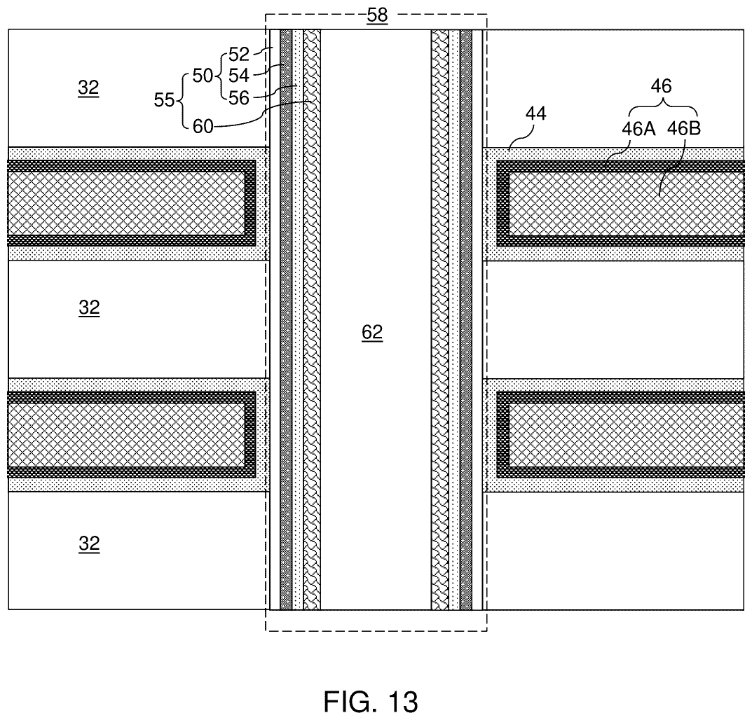

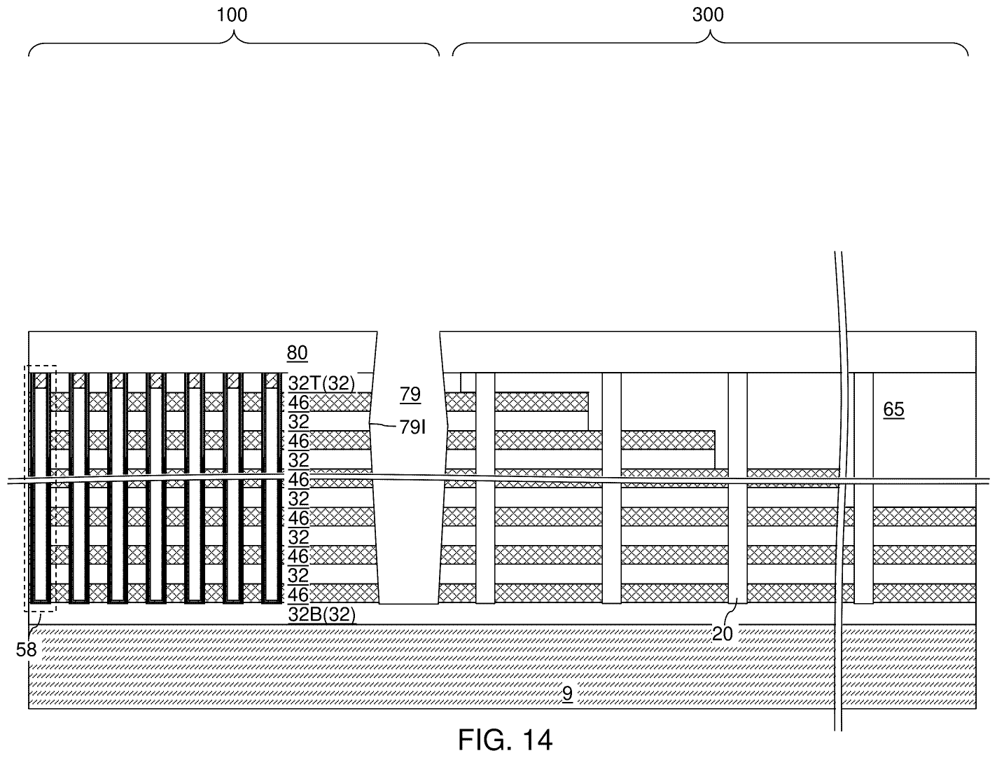

Referring to FIGS. 13 and 14, a metallic fill material can be conformally deposited in remaining volumes of the laterally-extending cavities 43. The metallic fill material may comprise, for example, Ti, Ta, Mo, Co, Ru, W, Cu, other transition metals, and/or alloys or layer stacks thereof. Excess portions of the at least one conductive material that are deposited in the lateral isolation trenches 79 or above the topmost insulating layer 32T can be removed by performing an etch-back process, which may comprise an isotropic etch process and/or an anisotropic etch process. Each remaining portion of the at least one conductive material filling a respective one of the laterally-extending cavities 43 constitutes an electrically conductive layer 46. An alternating stack of insulating layers 32 and electrically conductive layers 46 can be formed between each neighboring pair of lateral isolation trenches 79 over the carrier substrate 9. A plurality of alternating stacks of insulating layers 32 and electrically conductive layers 46 can be laterally spaced apart from each by the lateral isolation trenches 79. The electrically conductive layers 46 include the word lines and the select gate electrodes.

In one embodiment, at least one of the lateral isolation trenches 79 may comprise a respective pair of laterally-undulating lengthwise sidewalls formed by both the insulating layers 32 and electrically conductive layers 46. In one embodiment, each of the pair of laterally-undulating lengthwise sidewalls comprises a set of horizontally-convex and vertically-tapered surface segments that are adjoined among one another at edges.

A plurality of alternating stacks (32, 46) of insulating layers 32 and electrically conductive layers 46 are laterally spaced apart from each other by the lateral isolation trenches 79. Memory openings 49 vertically extend through a respective one of the alternating stacks (32, 46). Memory opening fill structures 58 can be located in a respective one of the memory openings 49. Each of the memory opening fill structures 58 comprises a respective vertical semiconductor channel 60 and a vertical stack of memory elements (e.g., portions of the memory film 50) located at levels of the electrically conductive layers 46.

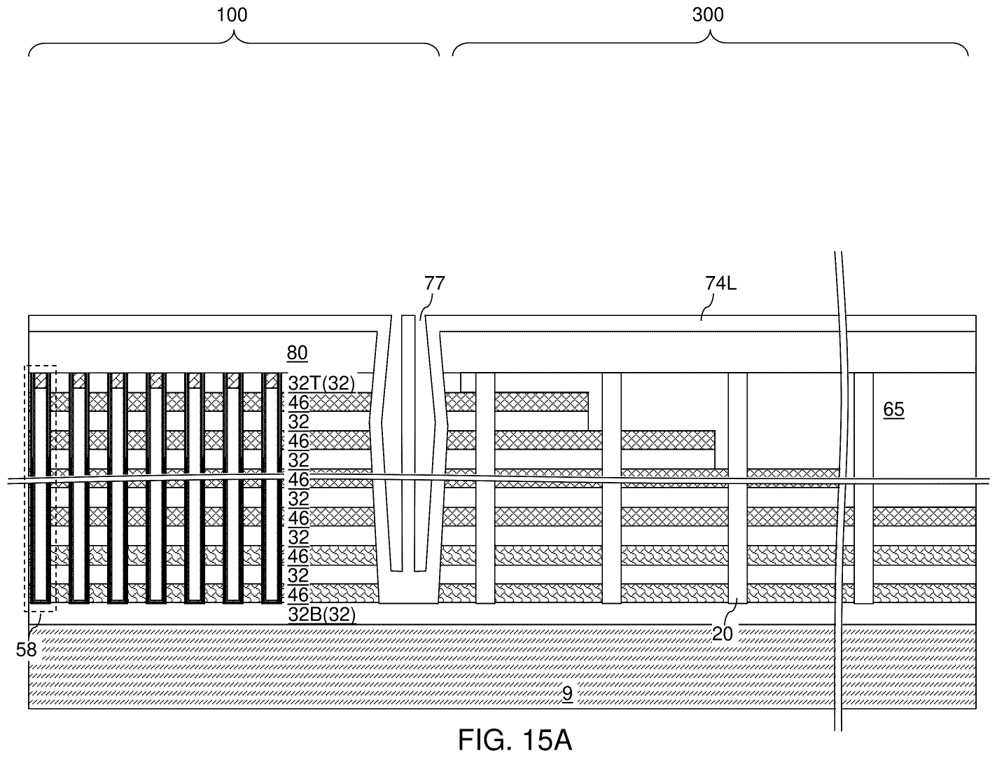

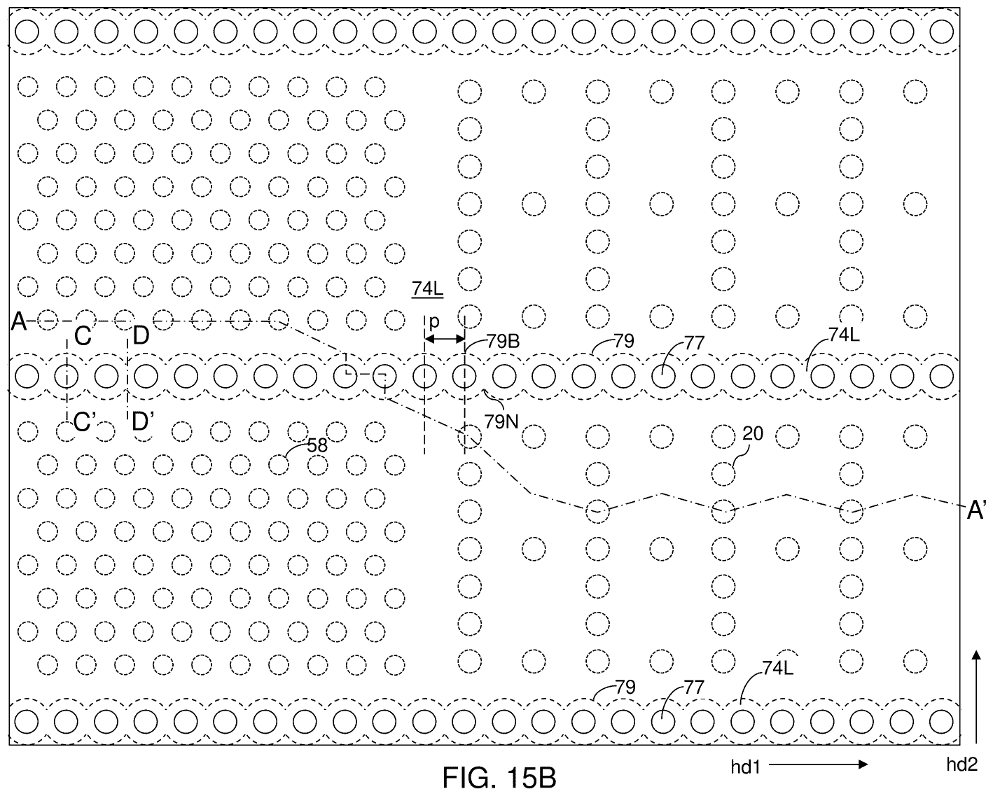

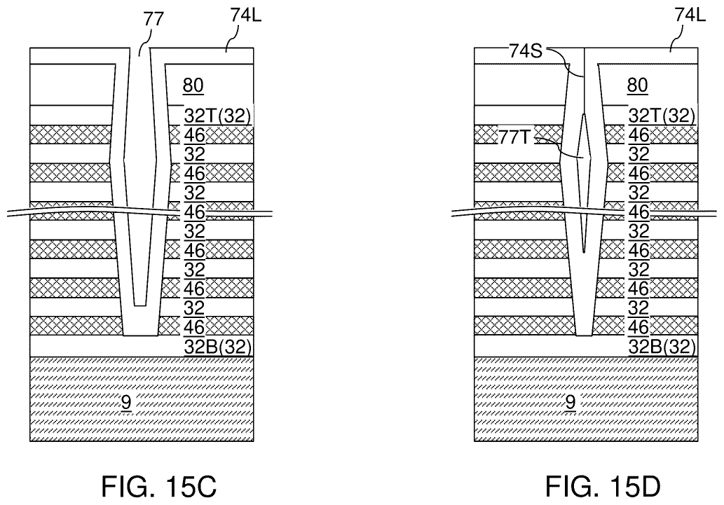

Referring to FIGS. 15A-15D, an insulating material may be conformally deposited in the lateral isolation trenches 79 to form an insulating spacer material layer 74L. The insulating spacer material layer 74L comprises an insulating material, such as undoped silicate glass (e.g., silicon oxide) or a doped silicate glass. The insulating spacer material layer 74L may be deposited by a conformal deposition process such as a low pressure chemical vapor deposition process. In one embodiment, at least one of the lateral isolation trenches 79 may comprise N neck regions 79N and (N+1) bulging regions 79B that are laterally interlaced among from each other along the first horizontal direction hd1. For example, N may be in an integer in a range from 2³ to 2¹⁴, such as from 2⁶ to 2¹⁰, although lesser and greater numbers may also be employed.

In one embodiment, the thickness of the insulating spacer material layer 74L may be greater than one half of the width of each neck region 79N within the horizontal plane including the top surface of the contact-level dielectric layer 80, is less than one half of the width of each neck region 79N at the height of the inflection lines 79I, and is less than one half of the width of each bulging region 79B within the horizontal plane including the top surface of the contact-level dielectric layer 80. In this case, each portion of the insulating spacer material layer 74L located within a respective lateral isolation trench 79 may comprise N laterally-extending tunnels 77T that laterally extend along a first horizontal direction hd1, as shown in FIG. 15D. The tunnels 77T comprise portions of the remaining unfilled voids 77 of the respective lateral isolation trench 79 that are embedded in the portions of the insulating spacer material layer 74L filling the neck regions 79N. A vertical seam 74S is the insulating spacer material layer 74L may be located over each respective tunnel 77T in the neck region 79N, as shown in FIG. 15D. Further, each portion of the insulating spacer material layer 74L located within a respective lateral isolation trench 79 may comprise (N+1) vertically extending portions that are adjoined to and interlaced with the N horizontally-extending portions of the respective portion of the insulating spacer material layer 74L.

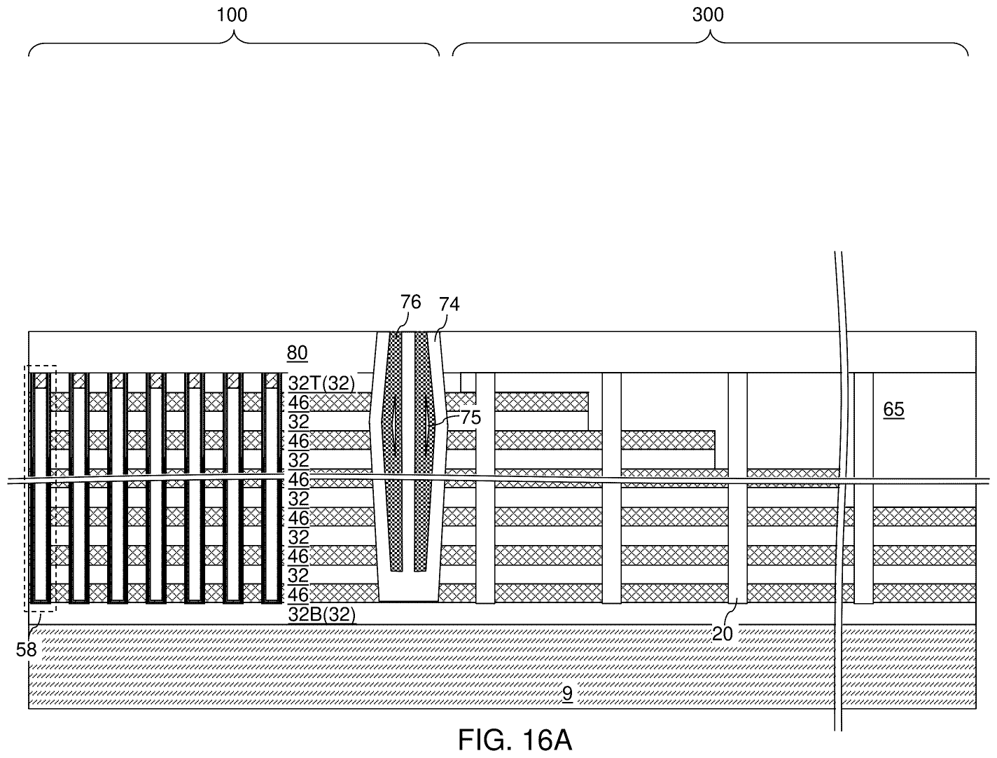

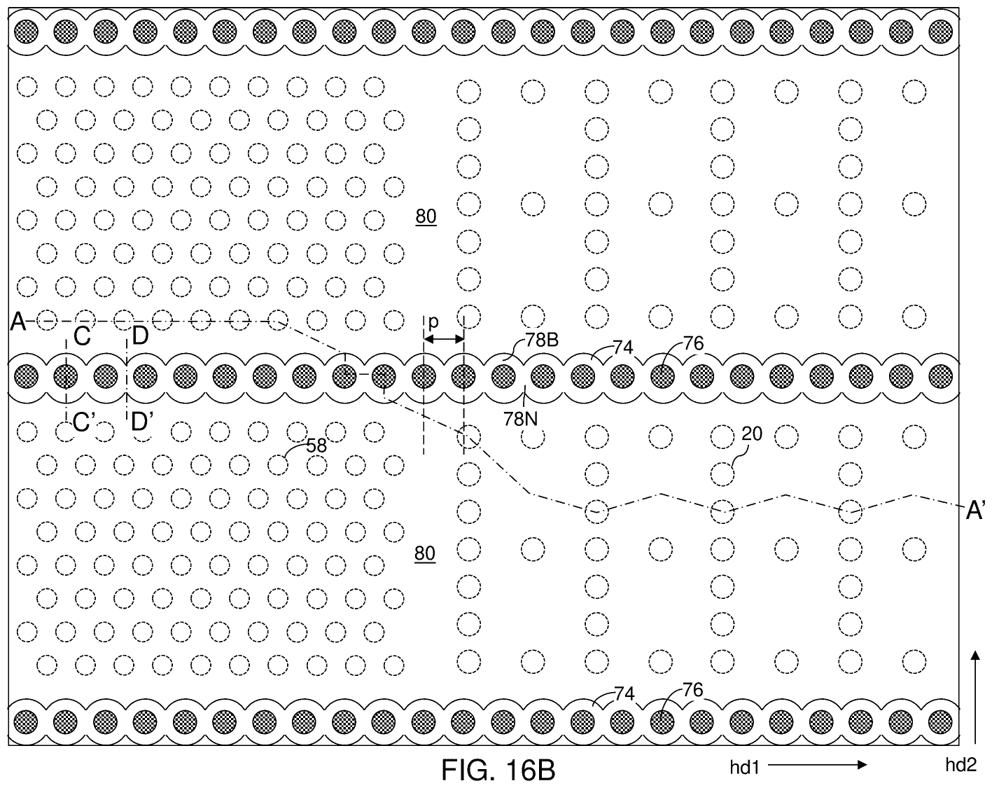

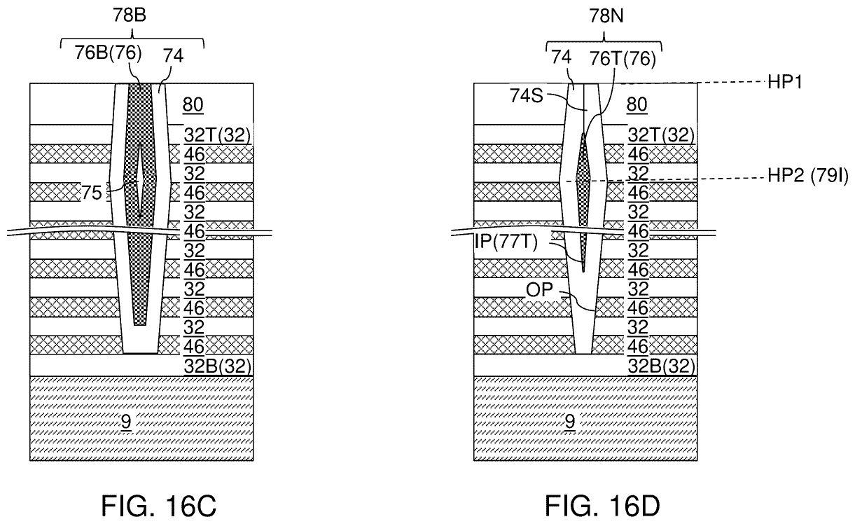

Referring to FIGS. 16A-16D, a conductive fill material can be conformally deposited in remaining volumes of the voids 77 in the lateral isolation trenches 79. In one embodiment, the conductive fill material may comprise and/or may consist essentially of a conductive metallic nitride material or a conductive metal material that counteracts the stress exerted on the substrate 9 by the electrically conductive layers 46. This reduces the substrate 9 warping and thus improves the properties of the memory device located over the substrate 9. In one embodiment, the conductive metal may comprise titanium, and the conductive metallic nitride material may comprise titanium nitride. The conductive fill material may be formed with edge seal fill in the kerf areas over the substrate 9.

Portions of the conductive fill material and the insulating spacer material layer 74L can be removed from above the horizontal plane including the top surface of the contact-level dielectric layer 80 by performing a planarization process, such as a chemical mechanical polishing process. Each remaining portion of the conductive fill material that remains in a respective lateral isolation trench 79 constitutes a conductive fill structure 76. Each remaining portion of the insulating spacer material layer 74L constitutes an insulating spacer, which is herein referred to as a peripheral spacer 74. Each contiguous combination of a conductive fill structure 76 and a peripheral spacer 74 constitutes a fill structure that fills a respective lateral isolation trench 79, and is herein referred to as a lateral isolation trench fill structure (74, 76). Each lateral isolation trench fill structure (74, 76) can be located in a lateral isolation trench 79, and can comprise a peripheral spacer 74 and a conductive fill structure 76.

In one embodiment shown in FIGS. 16A and 16C, the conductive fill structure 76 may partially fill the voids 77 which extend through the peripheral spacer 74 in the bulging regions 79B. Thus, embedded airgaps 75 may be located in the conductive fill structure 76 in the bulging regions 79B. Each airgap 75 is enclosed on all sides by the conductive fill structure 76. In one embodiment shown in FIG. 16D, the conductive fill structure 76 fills the tunnels 77T which extend through the peripheral spacer 74 in the neck regions 79N.

A first vertical cross-sectional view (such as the view of FIG. 16D) of the lateral isolation trench fill structure (74, 76) located in the neck region 79N (e.g., in a first vertical plane that is perpendicular to the first horizontal direction hd1) may comprise: an outer periphery OP of the peripheral spacer 74 which comprises a horizontal top surface segment located in a first horizontal plane HP1; and an inner periphery IP of the peripheral spacer 74 that is vertically spaced from and located entirely below the first horizontal plane HP1. In one embodiment, the horizontal top surface segment of the outer periphery OP of the peripheral spacer 74 is connected to the inner periphery IP of the peripheral spacer 74 by the vertically-extending seam 74S at which two vertical surfaces of the peripheral spacer 74 are in direct contact with each other.

In one embodiment shown in FIG. 16D, the outer periphery OP of the peripheral spacer 74 comprises a pair of tapered upper sidewall segments that are adjoined to a respective end of the horizontal top surface segment of the peripheral spacer 74. A lateral spacing between the pair of tapered upper sidewall segments decreases with a vertical distance from a second horizontal plane HP2 which corresponds to the inflection line 79I. In one embodiment, the outer periphery OP of the peripheral spacer 74 comprises a pair of tapered lower sidewall segments that underlie the pair of tapered upper sidewall segments of the peripheral spacer 74, and a lateral spacing between the pair of tapered lower sidewall segments increases with the vertical distance from the second horizontal plane HP2. In one embodiment, the conductive fill structure 76 fills an entire area within the inner periphery IP of the peripheral spacer 74 in the neck region 79N in the first vertical cross-sectional view.

In one embodiment, at least one of the lateral isolation trench fill structures (74, 76) has a width modulation along a second horizontal direction hd2 that is perpendicular to the first horizontal direction hd1 as a function of a lateral distance along the first horizontal direction hd1. In one embodiment, the lateral isolation trench fill structure (74, 76) comprises a periodic laterally alternating sequence of neck regions 78N located in the neck regions 79N of the trench 79 and having a minimum width along the second horizontal direction hd2, and bulging regions 78B located in the neck regions bulging region 79B of the trench 79 having a maximum width along the second horizontal direction hd2.

In one embodiment shown in FIGS. 16A and 16B, at least one of the lateral isolation trench fill structures (74, 76) has a height variation of the top surface of the conductive fill structure 76 along the first horizontal direction hd1. A top surface of the lateral isolation trench fill structure (74, 76) comprises a plurality of discrete top surface segments of the conductive fill structure 76 that are laterally spaced from each other by intervening portions of a top surface of the peripheral spacer 74.

In one embodiment shown in FIG. 16D, the peripheral spacer 74 comprises N laterally-extending tunnels 77T inside the inner periphery IP that laterally extend along the first horizontal direction hd1, where N is an integer greater than 23. The conductive fill structure 76 comprises N vertically-extending portions 76T that are located in the N laterally-extending tunnels 77 in the neck regions 78N. In one embodiment, the conductive fill structure 76 is a single continuous structure, and comprises (N+1) vertically-extending portions 76T located in the neck regions 78N that are interlaced with the N laterally-extending portions 76B located in the bulging regions 78B along the first horizontal direction hd1. The embedded airgaps 75 may be located in the N laterally-extending portions 76B located in the bulging regions 79B In one embodiment, the conductive fill structure 76 consists of at least one metallic nitride material.

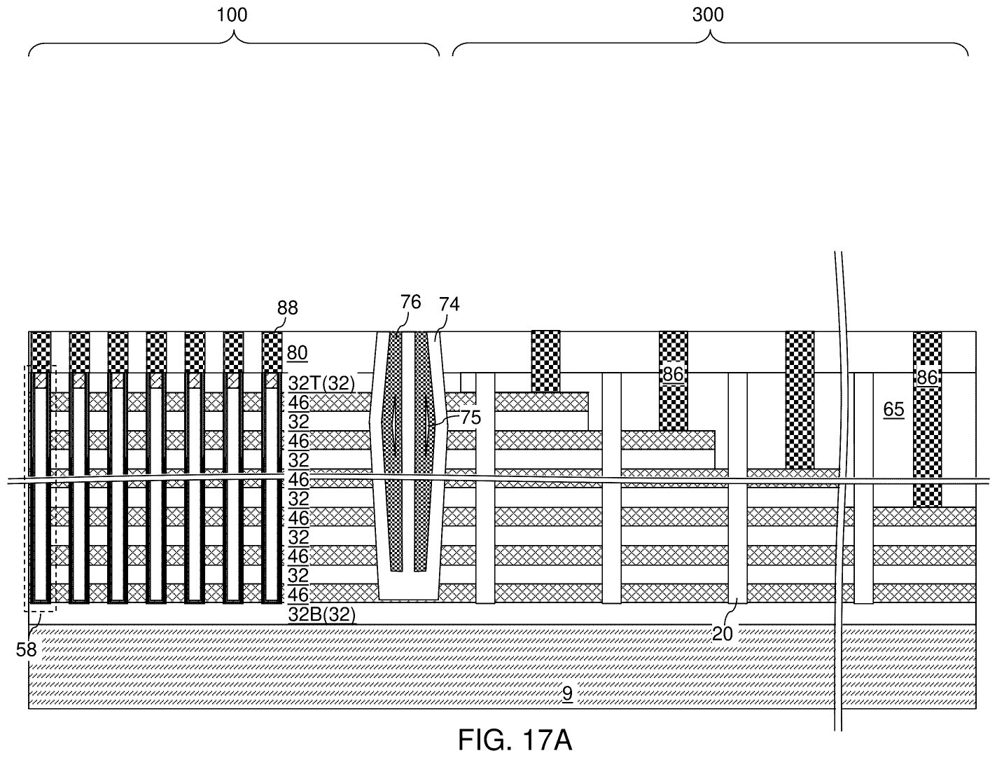

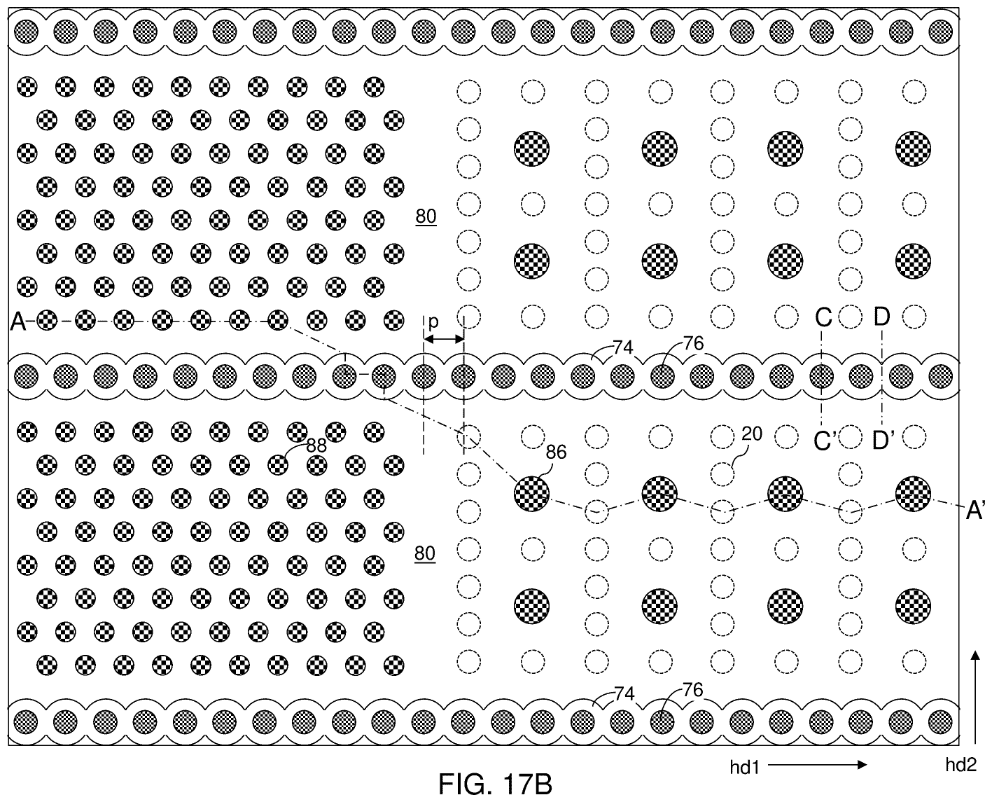

Referring to FIGS. 17A and 17B, a photoresist layer (not shown) can be applied over the contact-level dielectric layer 80, and can be lithographically patterned to form openings over each of the memory opening fill structures 58 over the horizontally-extending surfaces of the stepped surfaces in the contact region. An anisotropic etch process can be performed to transfer the pattern of the openings in the photoresist layer through the contact-level dielectric layer 80 and the stepped dielectric material portion 65. Drain contact via cavities can be formed through the contact-level dielectric layer 80 over the memory opening fill structures 58. Layer contact via cavities can be formed through the contact-level dielectric layer 80 and the stepped dielectric material portion 65 on a top surface of a respective one of the electrically conductive layers 46. The photoresist layer can be subsequently removed, for example, by ashing.

At least one conductive material, such as a combination of a metallic barrier material and a metallic fill material, can be deposited in the drain contact via cavities and the layer contact via cavities. Excess portions of the at least one conductive material can be removed from above the horizontal plane including the top surface of the contact-level dielectric layer 80 by a planarization process, which may employ a recess etch process and/or a chemical mechanical polishing process. Remaining portions of the at least one conductive material that fill the drain contact via cavities constitute drain contact via structures 88 contacting a top surface of a respective one of the drain regions 63. Remaining portions of the at least one conductive material that fill the layer contact via cavities constitute layer contact via structures 86 contacting a top surface of a respective one of the electrically conductive layers 46.

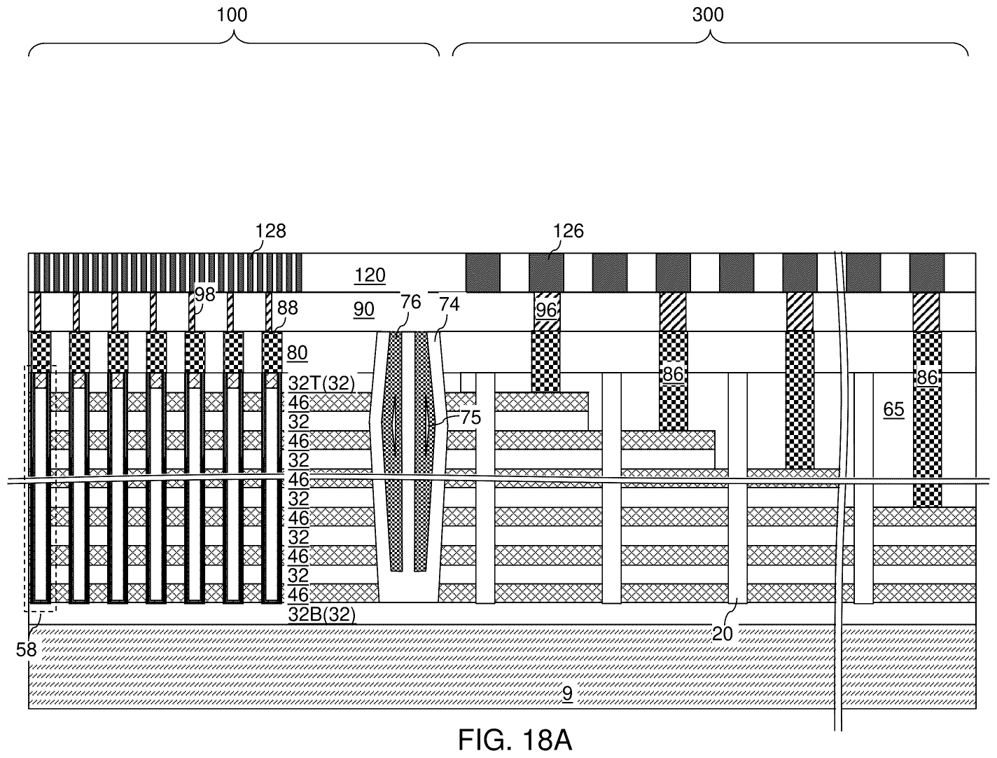

Referring to FIGS. 18A and 18B, a connection-level dielectric layer 90 can be formed above the contact-level dielectric layer 80. Connection via cavities can be formed through the connection-level dielectric layer 90, and can be filled with at least one conductive material (which may comprise at least one metallic material) to form connection-level via structures (98, 96). The connection-level via structures (98, 96) comprise drain connection via structures 98 that contact a respective one of the drain contact via structures 88, and layer connection via structures 96 that contact a respective one of the layer contact via structures 86.

A bit-line-level dielectric layer 120 can be formed above the connection-level dielectric layer 90. Bit-line-level line cavities can be formed through the bit-line-level dielectric layer 120, and can be filled with at least one conductive material (which may comprise at least one metallic material) to form bit-line-level metal lines (128, 126). The bit-line-level metal lines may comprise bit lines 128 that laterally extend along the second horizontal direction hd2, and bit-line-level interconnect metal lines 126 (not individually shown) that can be employed to provide electrical connection to the layer connection via structures 96.

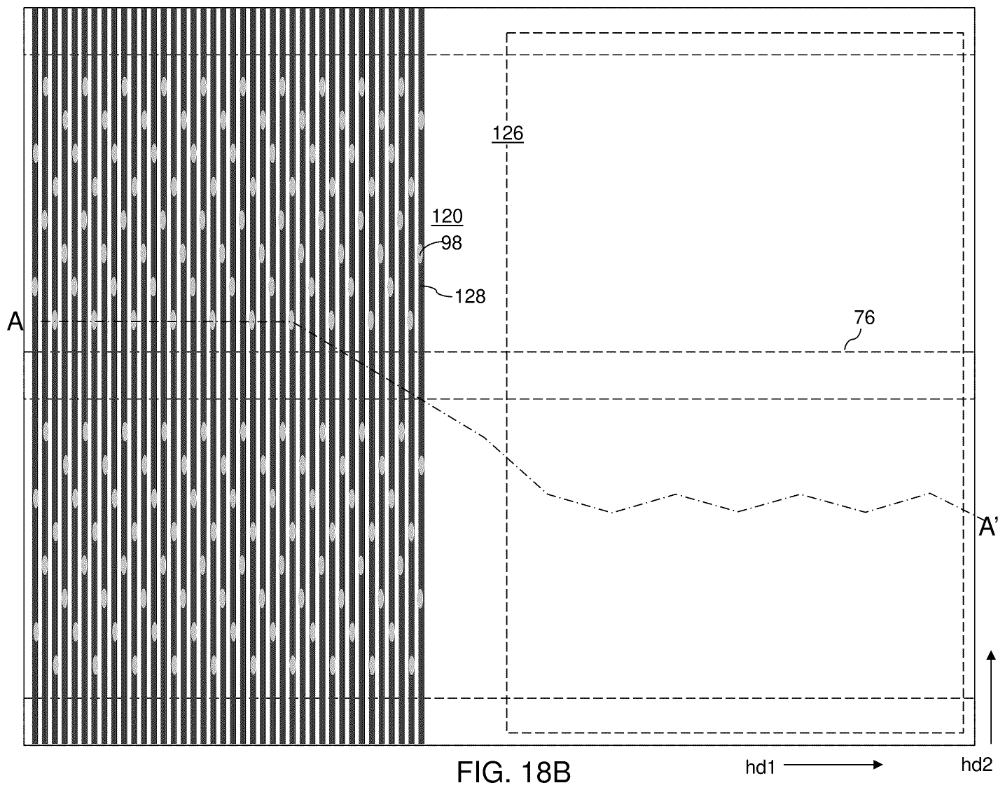

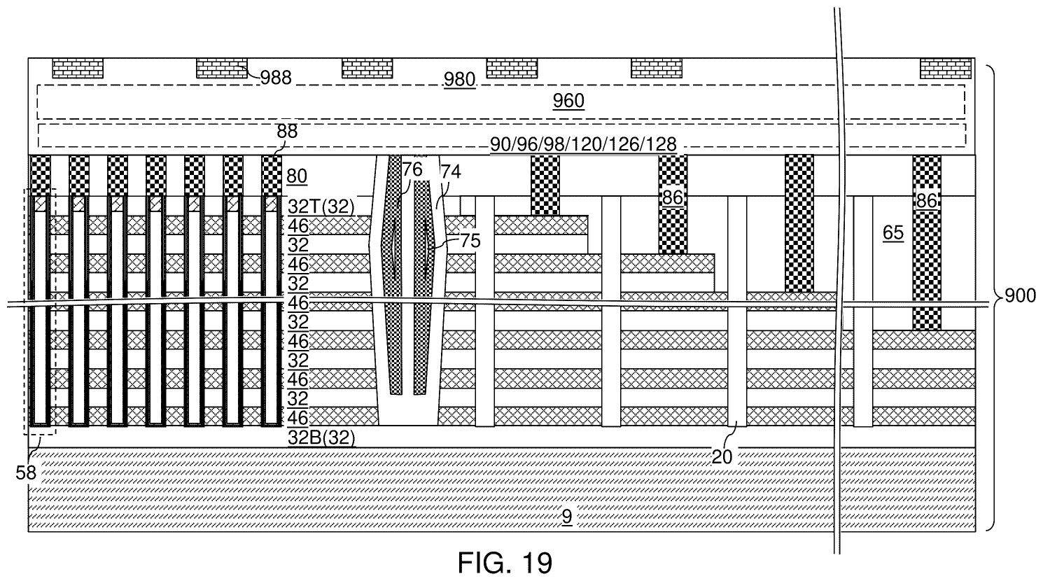

Referring to FIG. 19, additional dielectric material layers and additional metal interconnect structures can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The additional dielectric material layers that are formed above the contact-level dielectric layer 80 are herein referred to as memory-side dielectric material layers 960. The additional metal interconnect structures are collectively referred to as memory-side dielectric material layers 960. The memory-side dielectric material layers 960 comprise a bit-line-level dielectric material layer embedding the bit lines 128, which are a subset of the memory-side metal interconnect structures 980.

Metal bonding pads, which are herein referred to as memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the alternating stacks of insulating layers 32 and electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer among the memory-side dielectric material layers 960. The memory-side bonding pads 988 can be electrically connected to the memory-side metal interconnect structures 980.

In one embodiment, the memory die 900 may comprise: a three-dimensional memory array comprising an alternating stack (32, 46) of insulating layers 32 and electrically conductive layers 46, a two-dimensional array of memory openings 49 vertically extending through the alternating stack (32, 46), and a two-dimensional array of memory opening fill structures 58 located in the two-dimensional array of memory openings 49 and comprising a respective vertical stack of memory elements and a respective vertical semiconductor channel 60; a two-dimensional array of drain contact via structures 88 electrically connected to a respective one of the vertical semiconductor channels 60; and a two-dimensional array of layer contact via structures 86 electrically connected to a respective one of the electrically conductive layers 46, a subset of which functions as word lines for the three-dimensional memory array.

In summary, the memory die 900 comprises a memory device, memory-side metal interconnect structures 980, and memory-side bonding pads 988 embedded within memory-side dielectric material layers 960. The memory device may comprise a three-dimensional memory array including an alternating stack of insulating layers 32 and electrically conductive layers 46, and a two-dimensional array of NAND strings (e.g., the memory opening fill structures 58) vertically extending through the alternating stack (32, 46). In one embodiment, the electrically conductive layers 46 comprise word lines of the two-dimensional array of NAND strings. In one embodiment, the memory-side metal interconnect structures 980 comprise the bit lines 128 for the two-dimensional array of NAND strings.

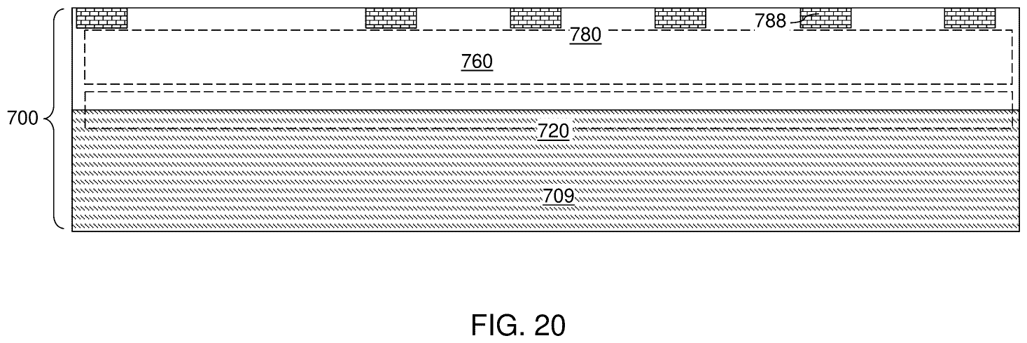

Referring to FIG. 20, a logic die 700 is provided. The logic die 700 comprises a peripheral circuit 720 that is formed on a logic-side substrate 709. According to an aspect of the present disclosure, the peripheral circuit 720 can be configured to control operation of the memory array within the memory die 900. For example, the peripheral circuit 720 may comprise word line driver regions, bit line driver regions, sense amplifier regions, input/output buffer regions, etc. Logic-side metal interconnect structures 780 embedded within logic-side dielectric material layers 760 can be formed over the peripheral circuit 720. The logic die 700 comprises logic-side bonding pads 788 embedded within logic-side dielectric material layers 760.

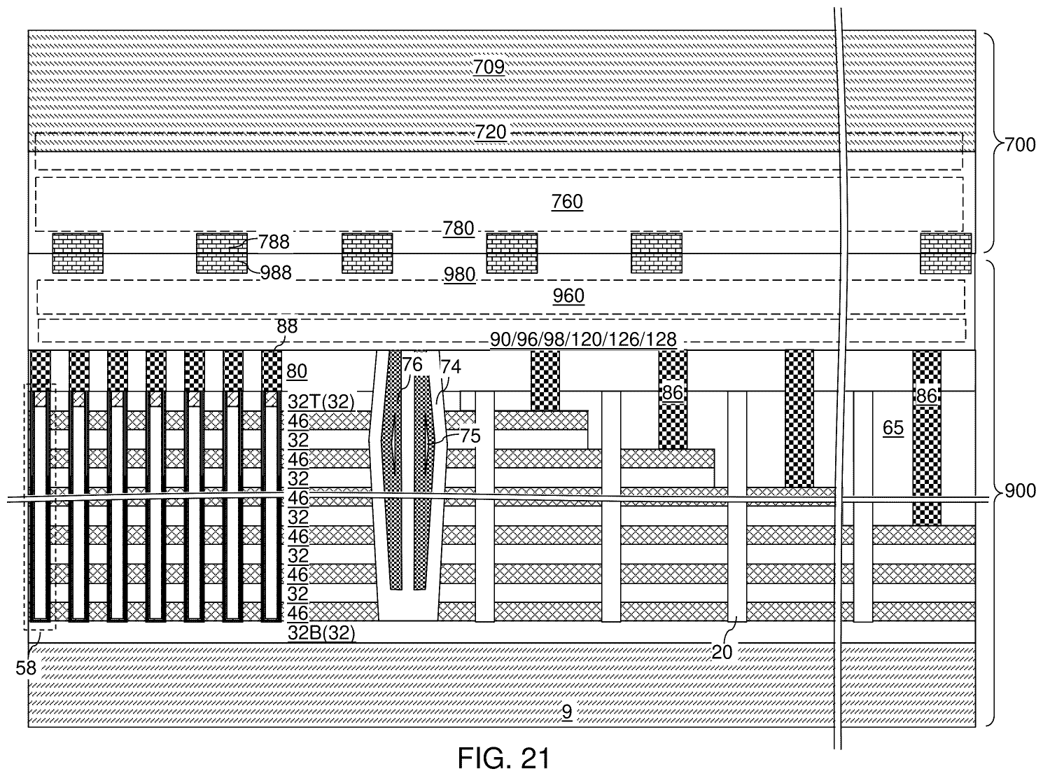

Referring to FIG. 21, a bonded assembly can be formed by bonding a logic die 700 with the memory die 900. The logic die 700 can be attached to the memory die 900, for example, by bonding the logic-side bonding pads 788 to the memory-side bonding pads 988. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

The logic die 700 can be attached to the memory die 900, for example, by bonding the logic-side bonding pads 788 to the memory-side bonding pads 988. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

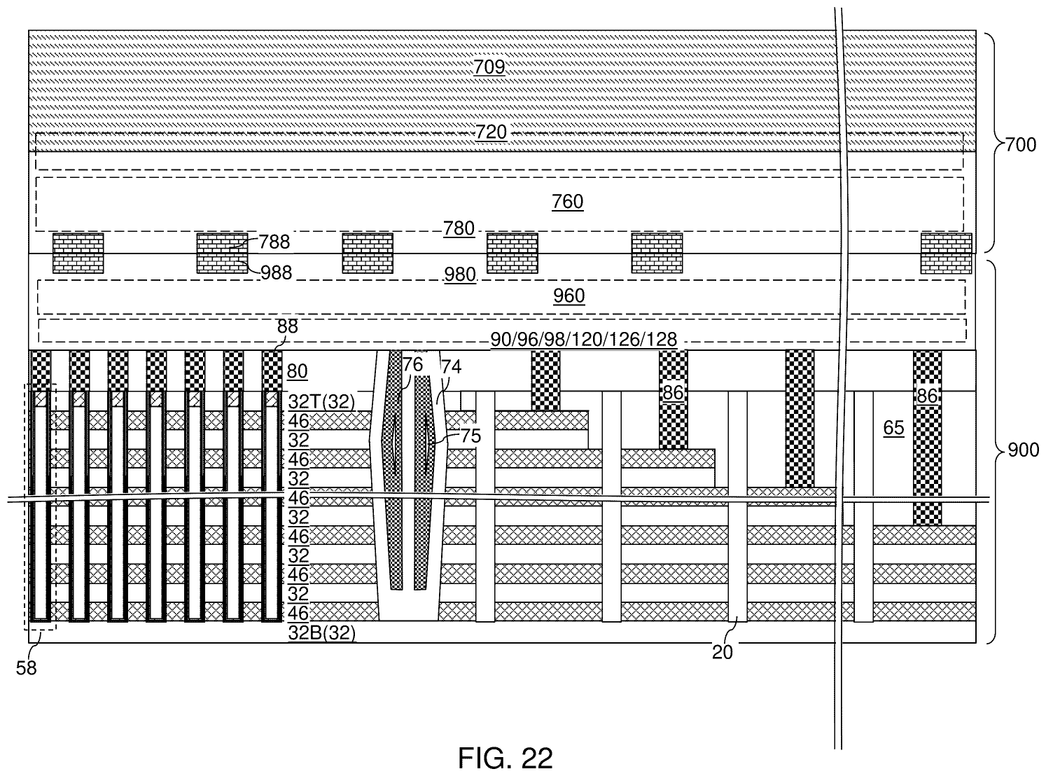

Referring to FIG. 22, the carrier substrate 9 can be removed, for example, by grinding, polishing, cleaving, an isotropic etch process, and/or an anisotropic etch process. If a polishing process such as a chemical mechanical polishing process is employed to remove the carrier substrate 9.

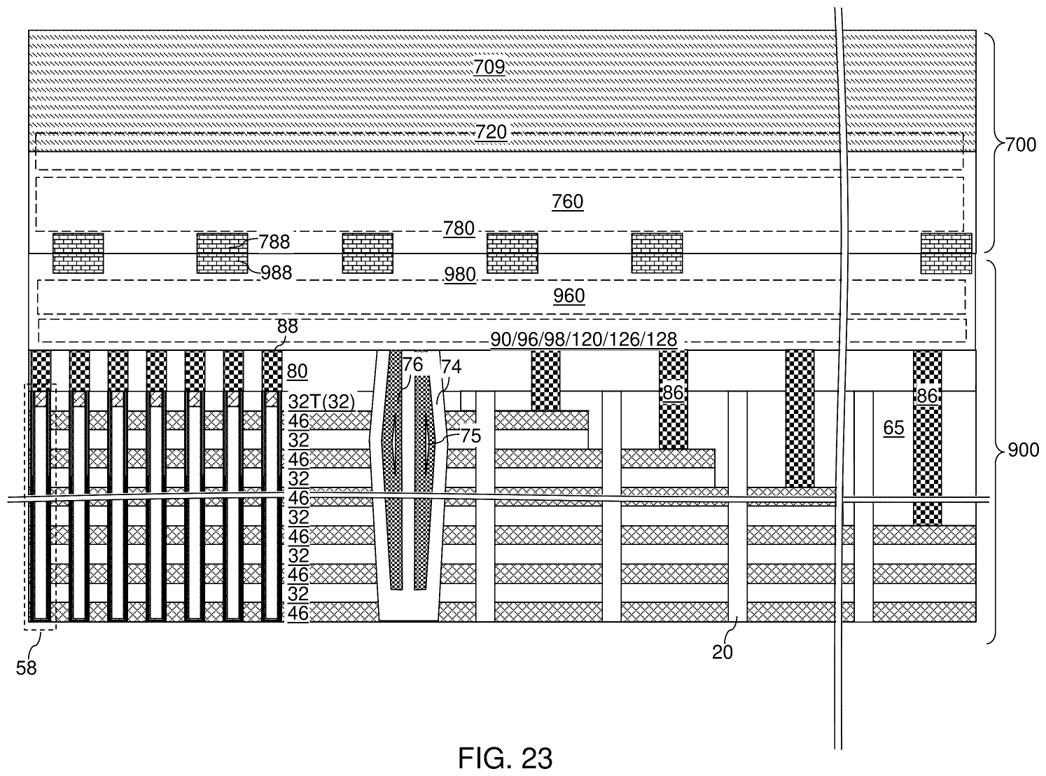

Referring to FIG. 23, the bottommost insulating layer 32B is also be removed during or after the substrate 9 removal process. For example, the bottommost insulating layer 32B may be removed by selective etching.

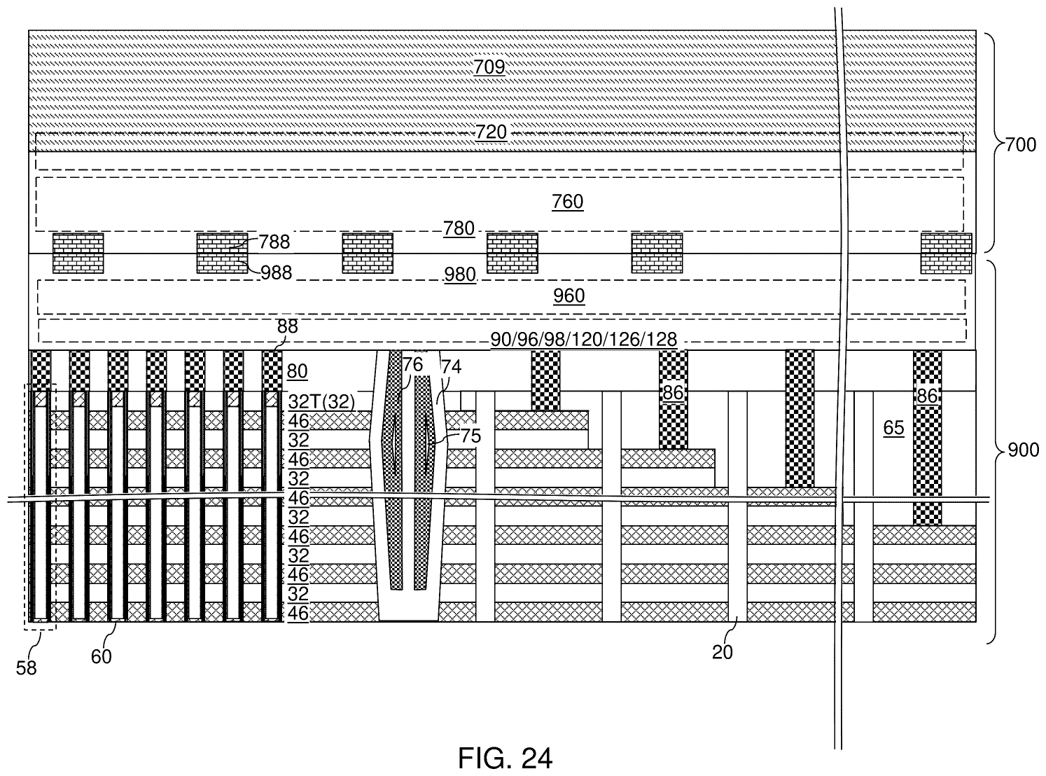

Referring to FIG. 24, bottom portions of the memory films 50 can be removed from each memory opening fill structure 58 by sequential selective etching relative to the material of the vertical semiconductor channels 60. Bottom surfaces of each vertical semiconductor channel 60 in the memory opening fill structures 58 can be physically exposed.

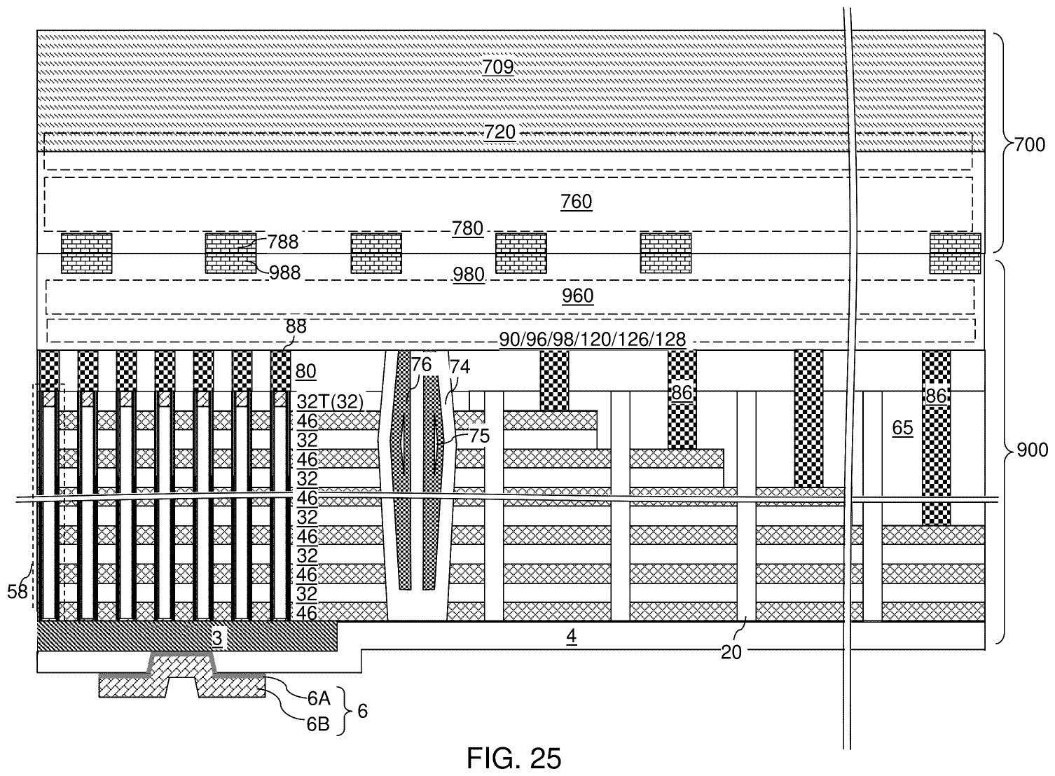

Referring to FIG. 25, a source layer 3 can be formed on the physically exposed bottom surfaces of the vertical semiconductor channels 60. The source layer 3 comprises a doped semiconductor material having a doping of the second conductivity type. A backside dielectric layer 4 can be formed over the source layer 3. At least one backside contact pad 6 can be formed through the backside dielectric layer 4. For example, the at least one backside contact pad 6 may comprise a source contact pad that is formed on the backside of the source layer 3. In one embodiment, each backside contact pad 6 may comprise a metallic barrier liner 6A and a metallic plate portion 6B.

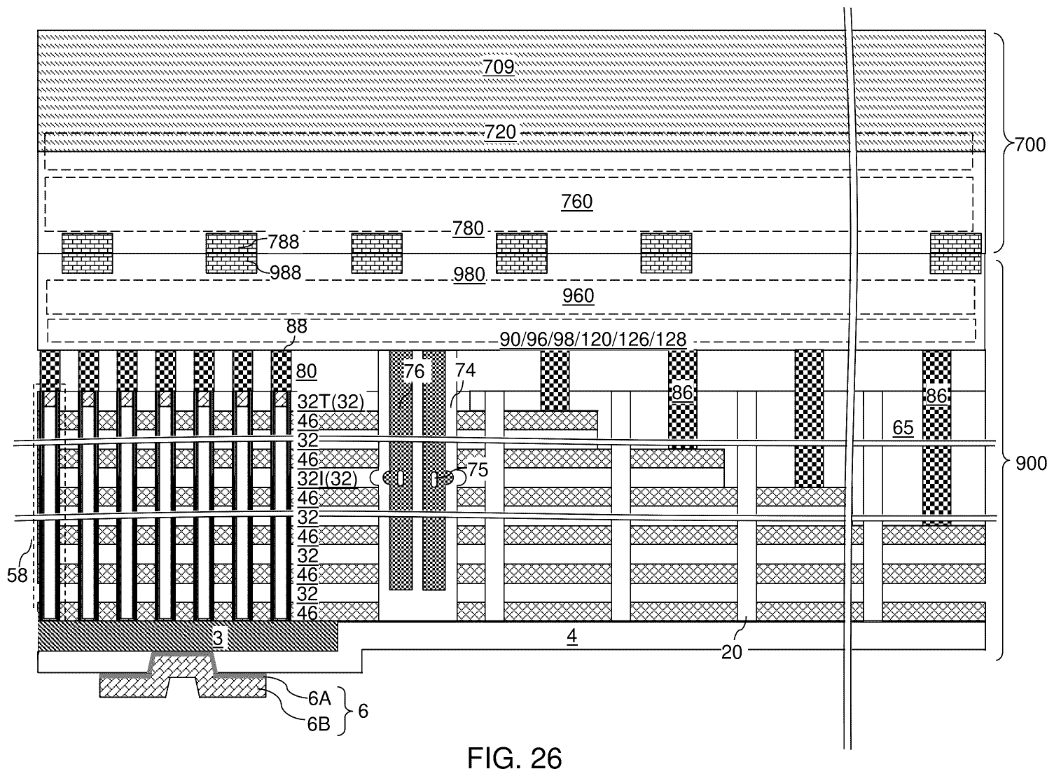

Referring to FIG. 26, an alternative configuration of the first exemplary structure is illustrated. The first alternative configuration of the first exemplary structure can be derived from the first exemplary structure illustrated in FIG. 25 by employing multiple vertical alternating sequences of continuous insulating layers 32 and continuous sacrificial material layers 42 with at least one intervening insulating layer, which is herein referred to as at least one inter-tier insulating layer 32I. In this case, the maximum lateral extent of each lateral isolation trench 79 may be at the level of an inter-tier insulating layer 32I, which is one of the insulating layers 32 within an alternating stack (32, 46).

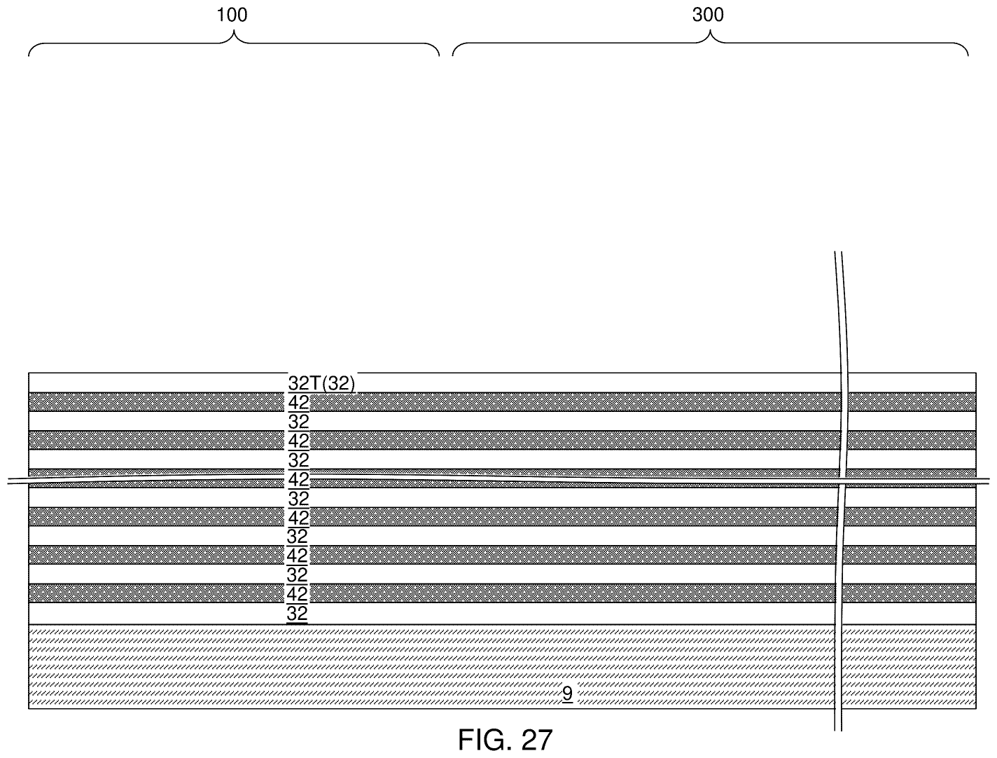

Referring to FIG. 27, a second exemplary structure according to a second embodiment of the present disclosure is illustrated. The second exemplary structure includes the alternating stack (32, 42) located over the substrate 9 which was described above with respect to FIG. 1.

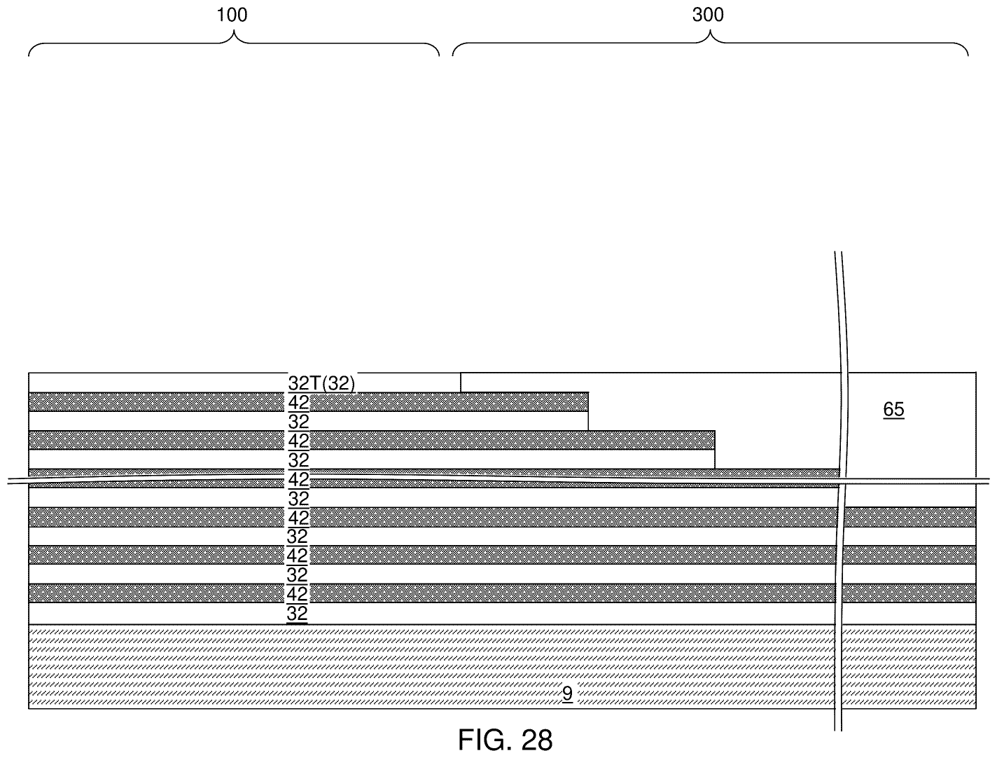

Referring to FIG. 28, the processing steps of FIG. 2 can be performed to form stepped surfaces and a stepped dielectric material portion 65.

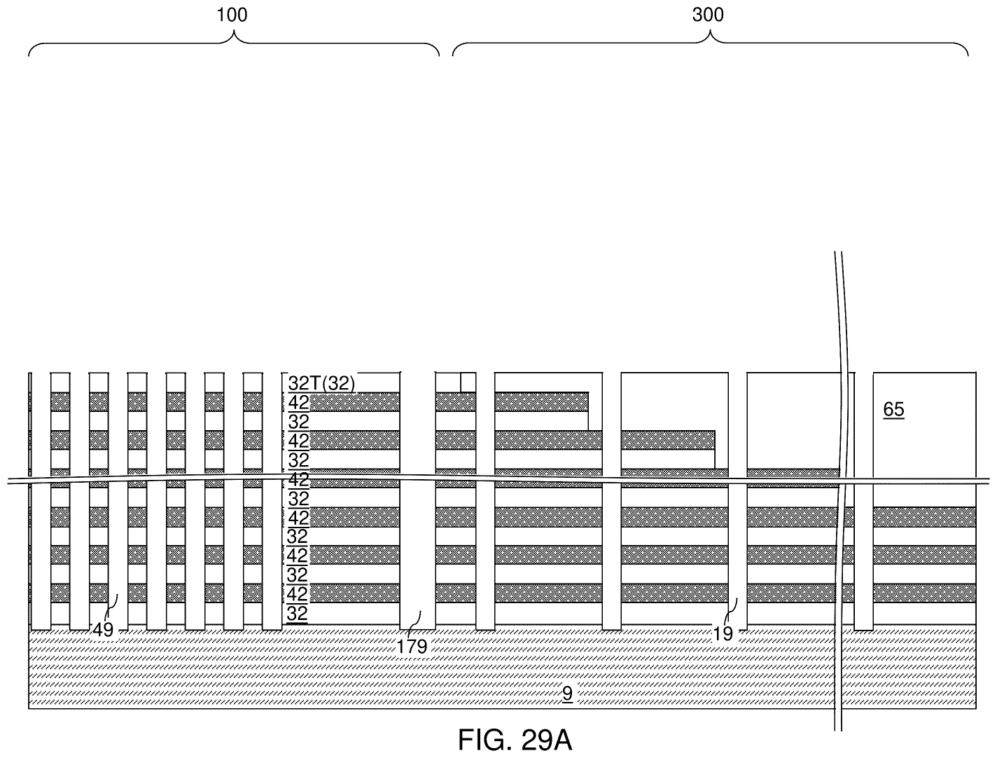

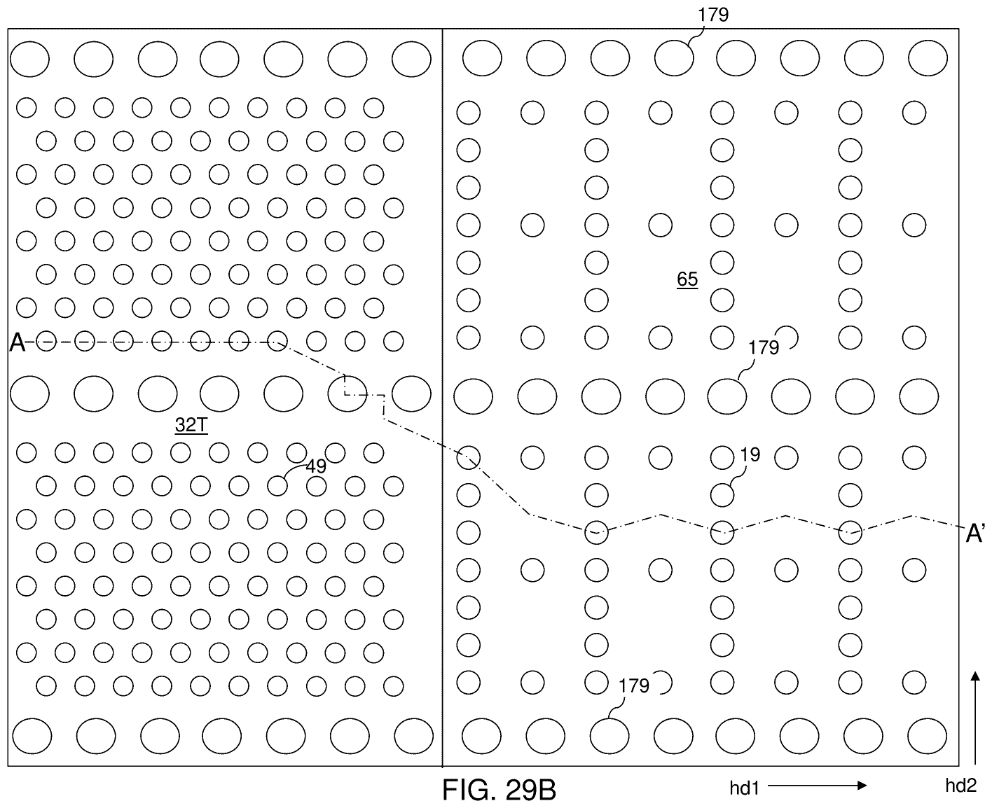

Referring to FIGS. 29A and 29B, the processing steps described with reference to FIGS. 3A and 3B and the first set of processing steps described with reference to FIGS. 9A and 9B can be performed at the same time using the same photoresist mask to form the memory openings 49, the support openings 19 and the discrete openings 179. The discrete openings 179 are formed between adjacent memory blocks.

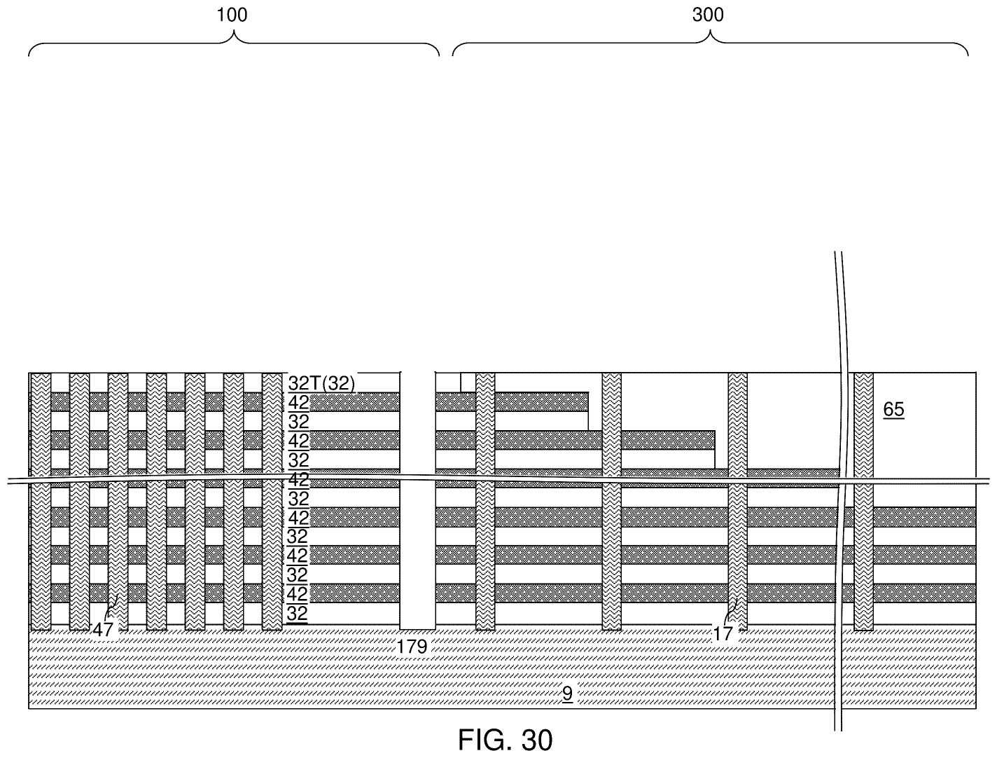

Referring to FIG. 30, the processing steps described with reference to FIG. 4 can be performed to form sacrificial memory opening fill structures 47 and sacrificial support opening fill structures 17 in the respective memory openings 49 and the support openings 19. The sacrificial material is removed from the discrete openings 179 to reopen the discrete openings 179.

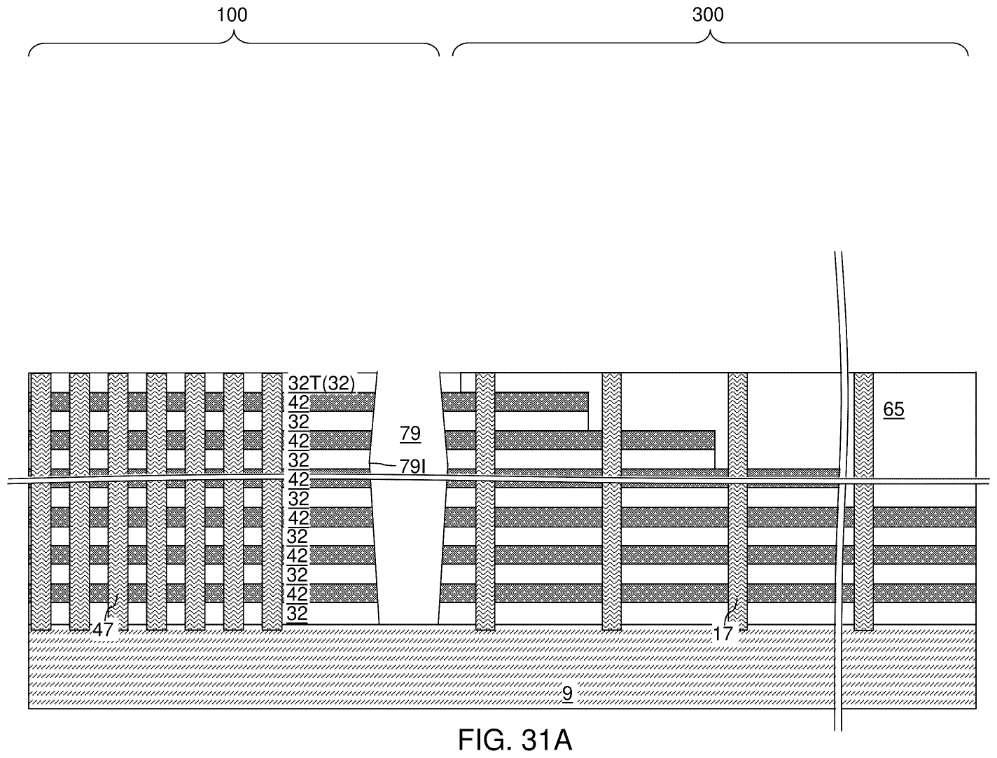

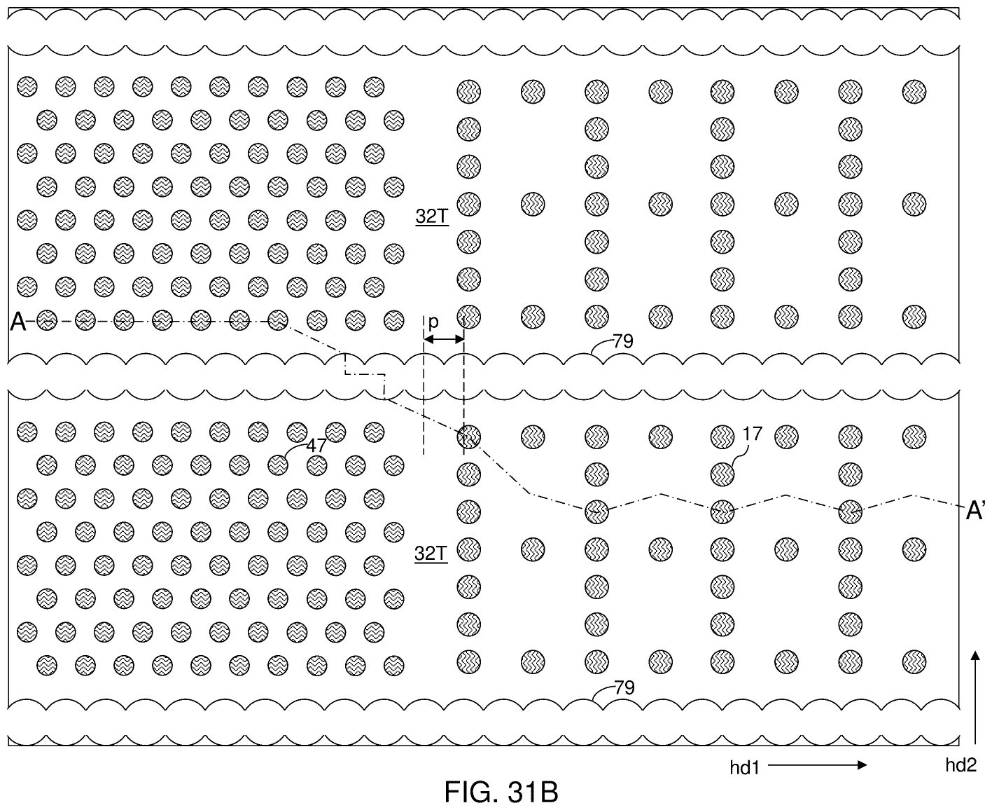

Referring to FIGS. 31A and 31B, the second set of processing steps described with reference to FIGS. 9A and 9B can be performed to expand the discrete openings 179 to form lateral isolation trenches 79. Generally, the lateral isolation trenches 79 in the second exemplary structure can be the same as the lateral isolation trenches 79 in the first exemplary structure.

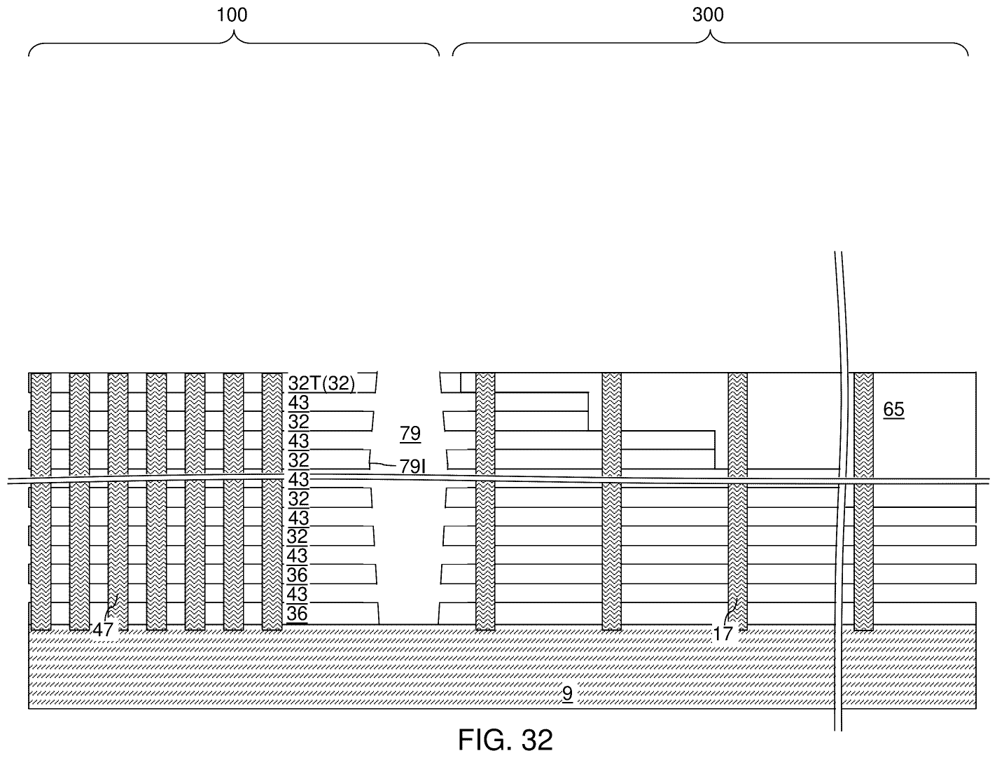

Referring to FIG. 32, the processing steps described with reference to FIG. 12 can be performed to remove the sacrificial material layers 42 and to form laterally-extending cavities 43. The isotropic etch process removes the material of the sacrificial material layers 42 selective to the materials of the insulating layers 32, the carrier substrate 9, and the sacrificial opening fill structures (47, 17).

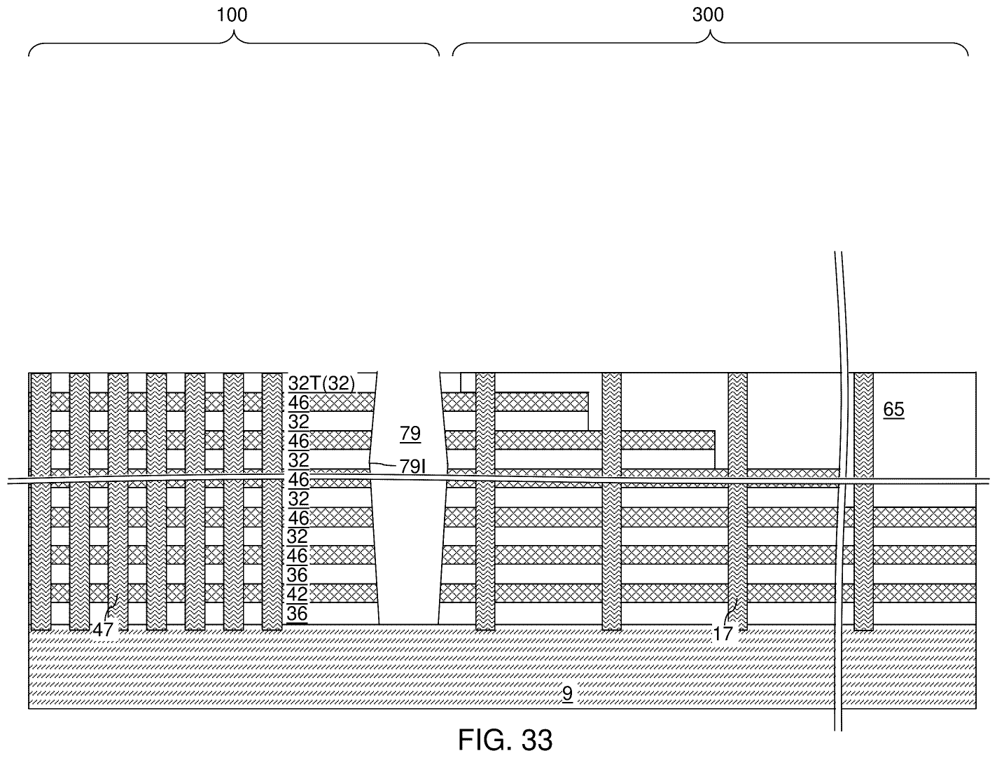

Referring to FIG. 33, the processing steps described with reference to FIGS. 11, 12, 13, and 14 can be performed to form the optional outer blocking dielectric layer 44 and to form the electrically conductive layers 46.

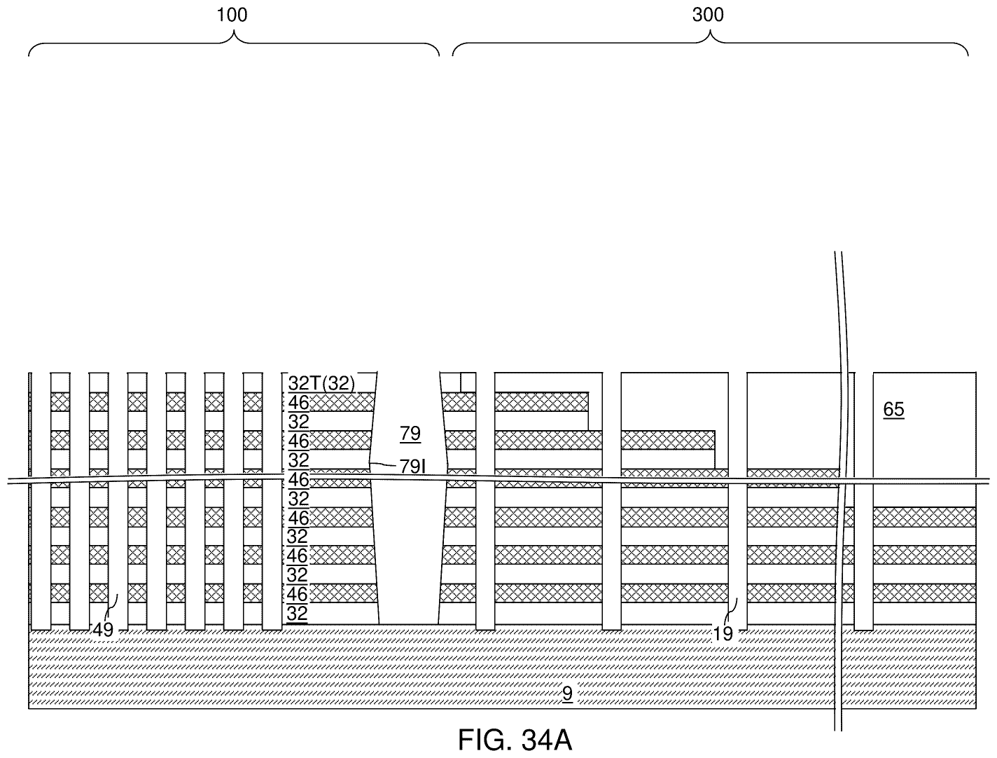

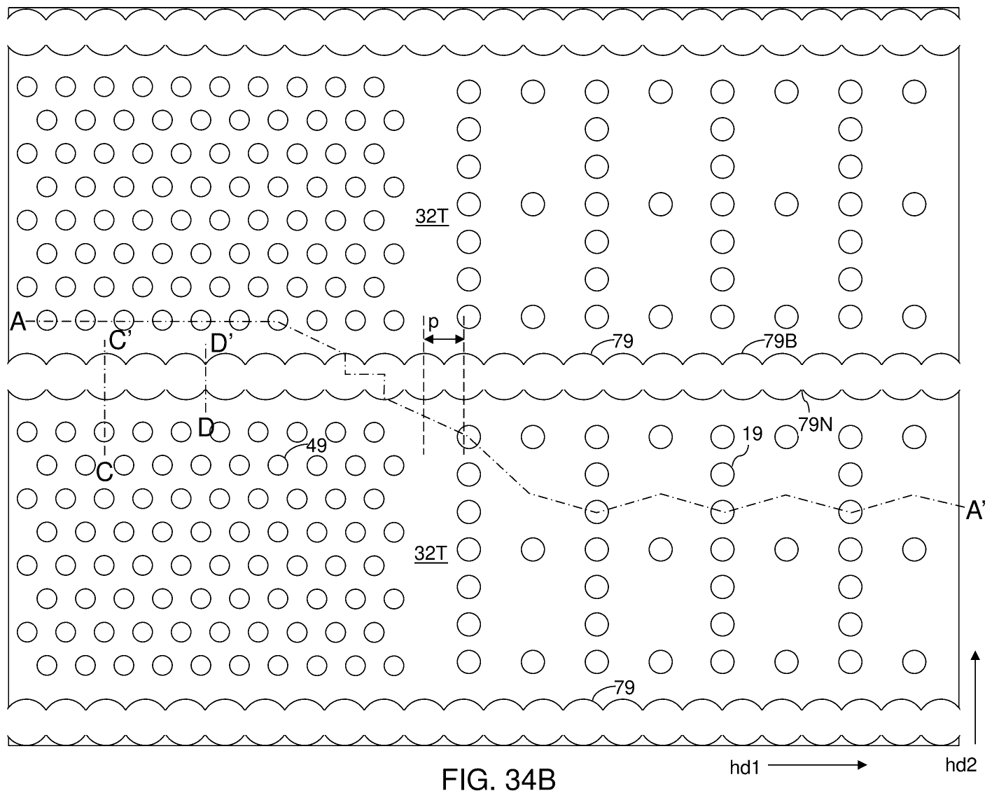

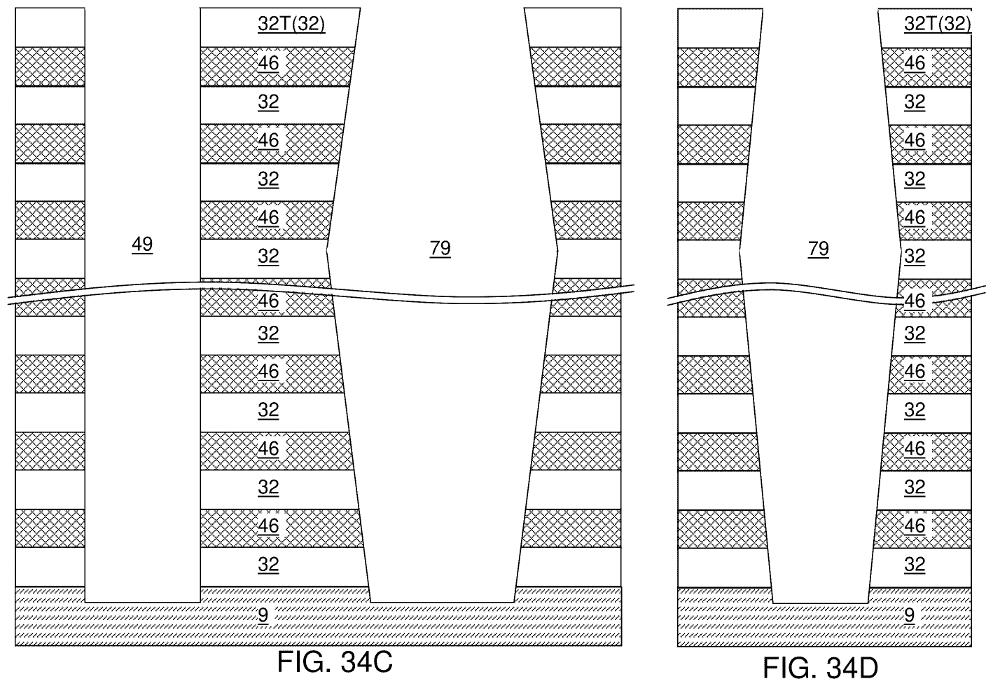

Referring to FIGS. 34A-34D, a selective removal process, such as an ashing process, can be performed to remove the sacrificial opening fill structures (47, 17) from the memory openings 49 and from the support openings 19.

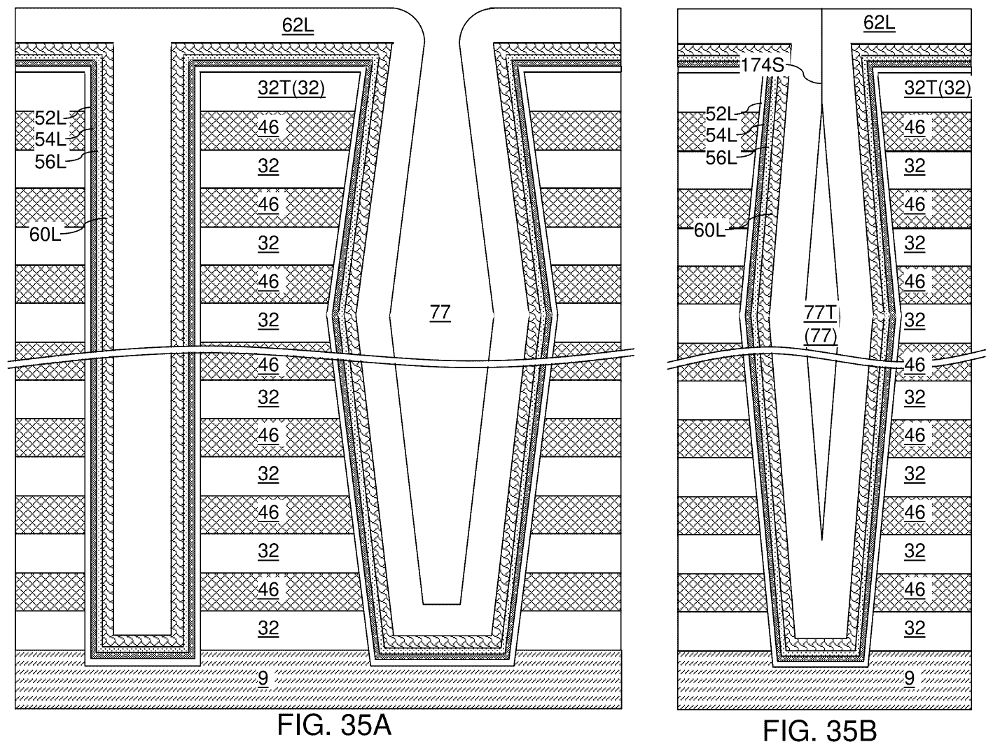

Referring to FIGS. 35A and 35B, an optional continuous blocking dielectric layer 52L, a continuous memory material layer 54L, an optional continuous dielectric liner 56L, a semiconductor channel material layer 60L, and a dielectric core layer 62L can be sequentially deposited in the memory openings 49, in the support openings 19, and in the lateral isolation trenches 79. The continuous blocking dielectric layer 52L may have the same material composition and the same thickness as the blocking dielectric layer 52 in the first exemplary structure. The continuous memory material layer 54L may have the same material composition and the same thickness as the memory material layer 54 in the first exemplary structure. The continuous dielectric liner 56L may have the same material composition and the same thickness as the dielectric liner 56 in the first exemplary structure.

According to an aspect of the present disclosure, the dielectric core layer 62L may be deposited by a conformal deposition process such as a low pressure chemical vapor deposition process. In one embodiment, at least one of the lateral isolation trenches 79 may comprise N neck regions 79N and (N+1) bulging regions 79B that are laterally interlaced with each other along the first horizontal direction hd1. For example, N may be in an integer in a range from 23 to 214, such as from 26 to 210, although lesser and greater numbers may also be employed.

The thickness of the dielectric core layer 62L may be greater than one half of the width of an unfilled volume of each neck region 79N within the horizontal plane including the top surface of the contact-level dielectric layer 80 after formation of the semiconductor channel material layer 60L, is less than one half of the width of the unfilled volume of each neck region 79N at the height of the inflection lines 79I after formation of the semiconductor channel material layer 60L, and is less than one half of the width of an unfilled volume of each bulging region 79B within the horizontal plane including the top surface of the contact-level dielectric layer 80 after formation of the semiconductor channel material layer 60L. In this case, each portion of the dielectric core layer 62L located within a respective lateral isolation trench 79 may comprise N laterally-extending tunnels 77T that laterally extend along a first horizontal direction hd1, as shown in FIG. 35D, and N+1 voids 77, as shown in FIG. 35C. Further, each portion of the dielectric core layer 62L located within a respective lateral isolation trench 79 may comprise (N+1) vertically extending portions that are adjoined to and interlaced with the N horizontally-extending portions of the respective portion of the dielectric core layer 62L.

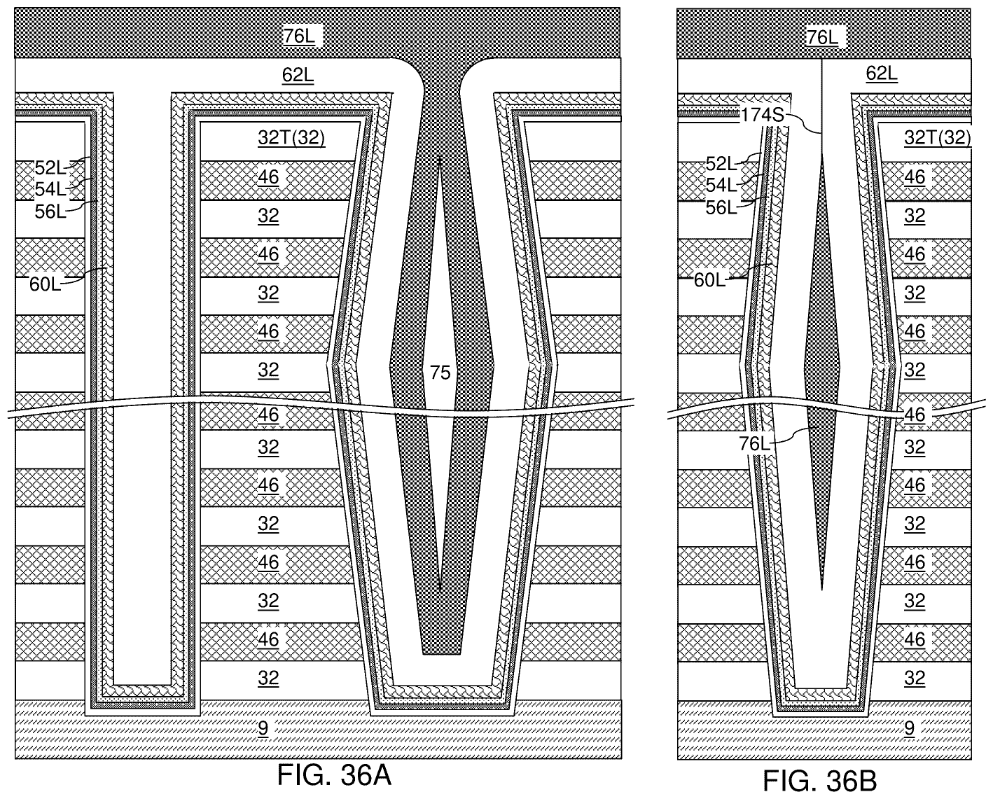

Referring to FIGS. 36A and 36B, a conductive fill material can be conformally deposited in remaining volumes of the voids 77 in the lateral isolation trenches 79 to form a conductive fill material layer 76L. According to an aspect of the present disclosure, the conductive fill material may comprise and/or may consist essentially of a conductive metallic nitride material. In one embodiment, the conductive metallic nitride material may comprise, and/or may consist essentially of, TiN, TaN, WN, or MoN.

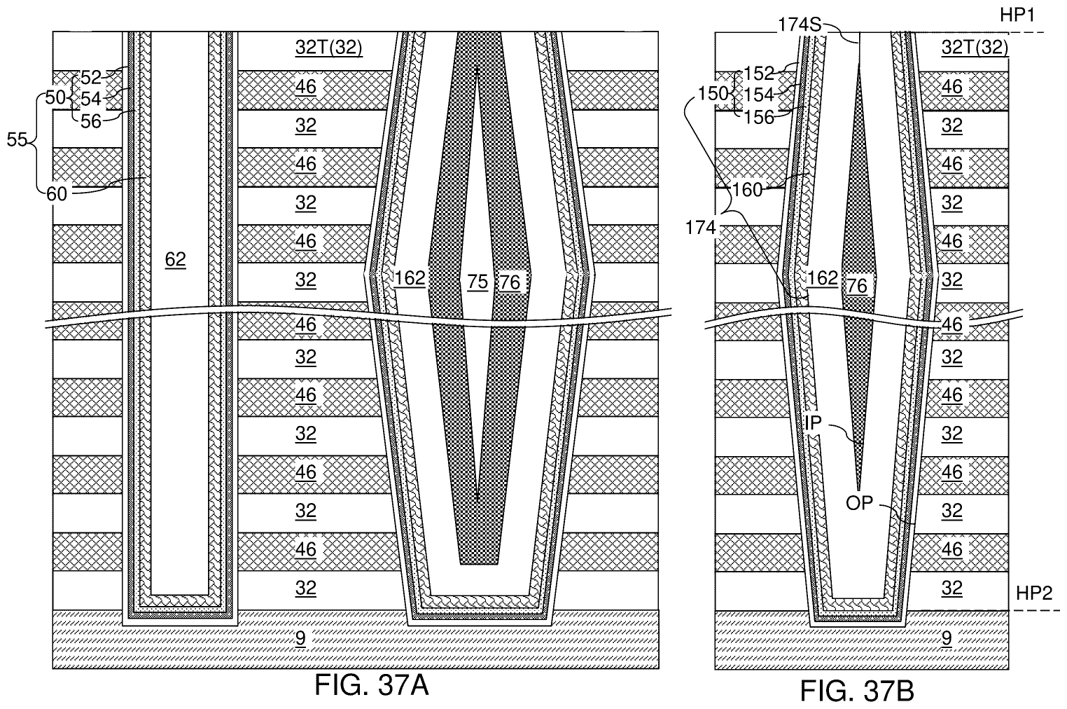

Referring to FIGS. 37A and 37B, portions of the conductive fill material, the dielectric core layer 62L, the semiconductor channel material layer 60L, the continuous dielectric liner 56L, the continuous memory material layer 54L, and the continuous blocking dielectric layer 52L can be removed from above the horizontal plane including the top surface of the topmost insulating layer 32T by performing a planarization process such as a chemical mechanical polishing process.

Each remaining portion of the conductive fill material that remains in a respective lateral isolation trench 79 constitutes a conductive fill structure 76. Each remaining portion of the dielectric core layer 62L that remains in a respective lateral isolation trench 79 constitutes a trench dielectric spacer 162. Each remaining portion of the semiconductor channel material layer 60L that remains in a respective lateral isolation trench 79 constitutes a trench semiconductor spacer 160. Each remaining portion of the continuous dielectric liner 56L that remains in a respective lateral isolation trench 79 constitutes a third trench spacer liner 156. Each remaining portion of the continuous memory material layer 54L that remains in a respective lateral isolation trench 79 constitutes a second trench spacer liner 154. Each remaining portion of the continuous blocking dielectric layer 52L that remains in a respective lateral isolation trench 79 constitutes a first trench spacer liner 152. Each contiguous combination of a first trench spacer liner 152, a second trench spacer liner 154, and a third trench spacer liner 156 constitutes a composite trench spacer liner 150. Each continuous combination of a composite trench spacer liner 150, a trench semiconductor spacer 160, and a trench dielectric spacer 162 comprises a peripheral spacer 174. Embedded airgaps 75 may be located in the conductive fill structure 76 in the bulging regions 79B of the trenches 79.

Each remaining portion of the continuous dielectric liner 56L that remains in a respective memory opening 49 or in a respective support opening 19 constitutes a dielectric liner (e.g., tunneling dielectric) 56. Each remaining portion of the continuous memory material layer 54L that remains in a respective memory opening 49 or in a respective support opening 19 constitutes a memory material layer 54. Each remaining portion of the continuous blocking dielectric layer 52L that remains in a respective memory opening 49 or in a respective support opening 19 constitutes a blocking dielectric layer 52. Each contiguous combination of a blocking dielectric layer 52, a memory material layer 54, and a dielectric liner 56 constitutes a memory film 50. Each remaining portion of the semiconductor channel material layer 60L that remains in a respective memory opening 49 or in a respective support opening 19 constitutes a vertical semiconductor channel 60. Each remaining portion of the dielectric core layer 62L that remains in a respective memory opening 49 or in a respective support opening 19 constitutes a dielectric core 62. Each contiguous combination of a vertical semiconductor channel 60 and a memory film 50 constitutes a memory stack structure 55.

The set of all material portions that fills a memory opening 49 constitutes a memory opening fill structure 58. The set of all material portions that fills a support opening 19 constitutes a support pillar structure 20. Each contiguous combination of a conductive fill structure 76 and a peripheral spacer 174 constitutes a fill structure that fills a respective lateral isolation trench 79, and is herein referred to as a lateral isolation trench fill structure (174, 76). Each lateral isolation trench fill structure (174, 76) can be located in a lateral isolation trench 79, and can comprise a peripheral spacer 174 and a conductive fill structure 76. In the second embodiment, the peripheral spacer 174 comprises the same set of materials as the combination of the memory film 50, vertical semiconductor channel and dielectric core 62 in the memory openings 49.

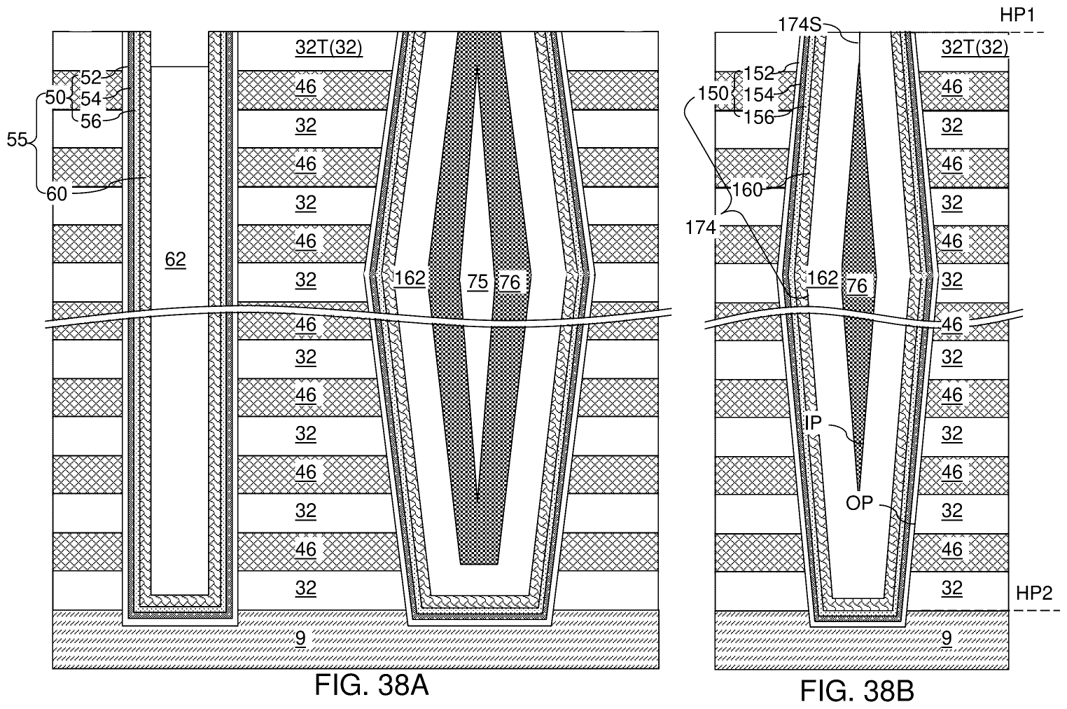

Referring to FIGS. 38A and 38B, a photoresist layer (not shown) can be applied over the second exemplary structure, and can be lithographically patterned to form openings that overlie the areas of the dielectric cores 62 of the memory opening fill structures 58. A recess etch process can be performed to vertically recess the dielectric cores 62.

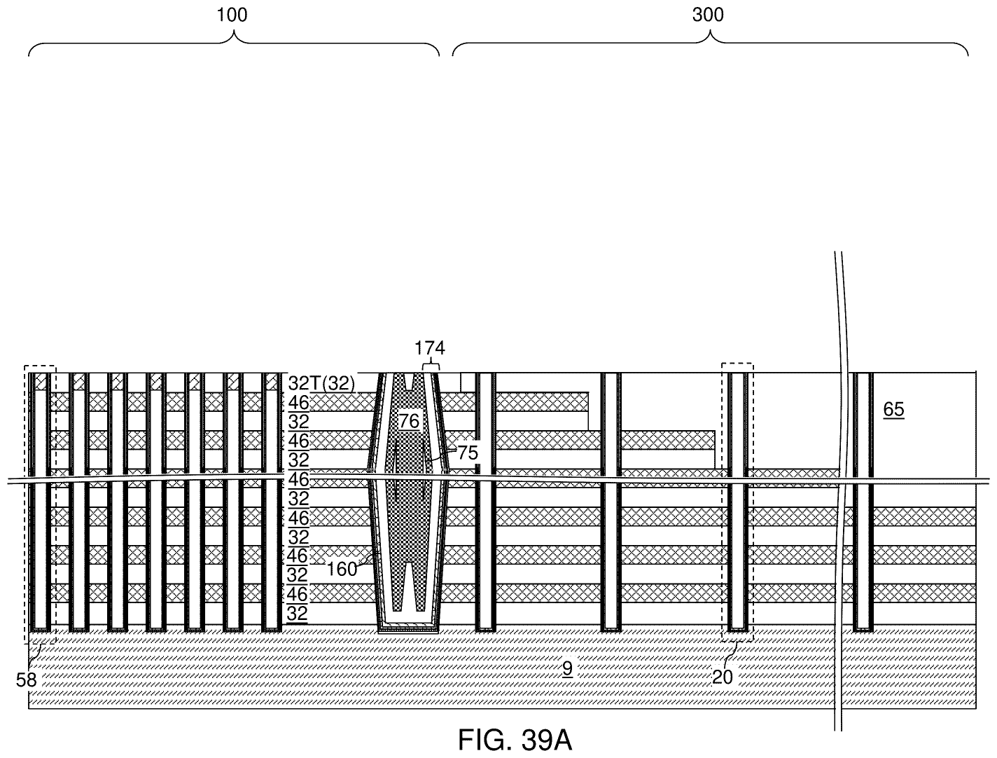

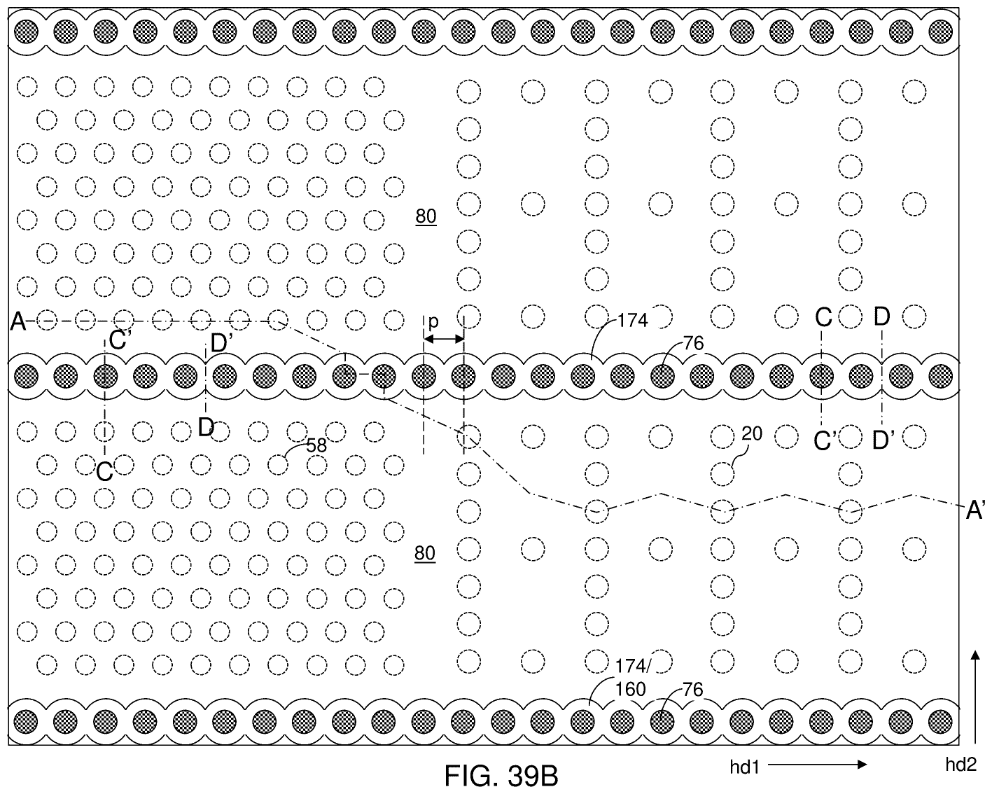

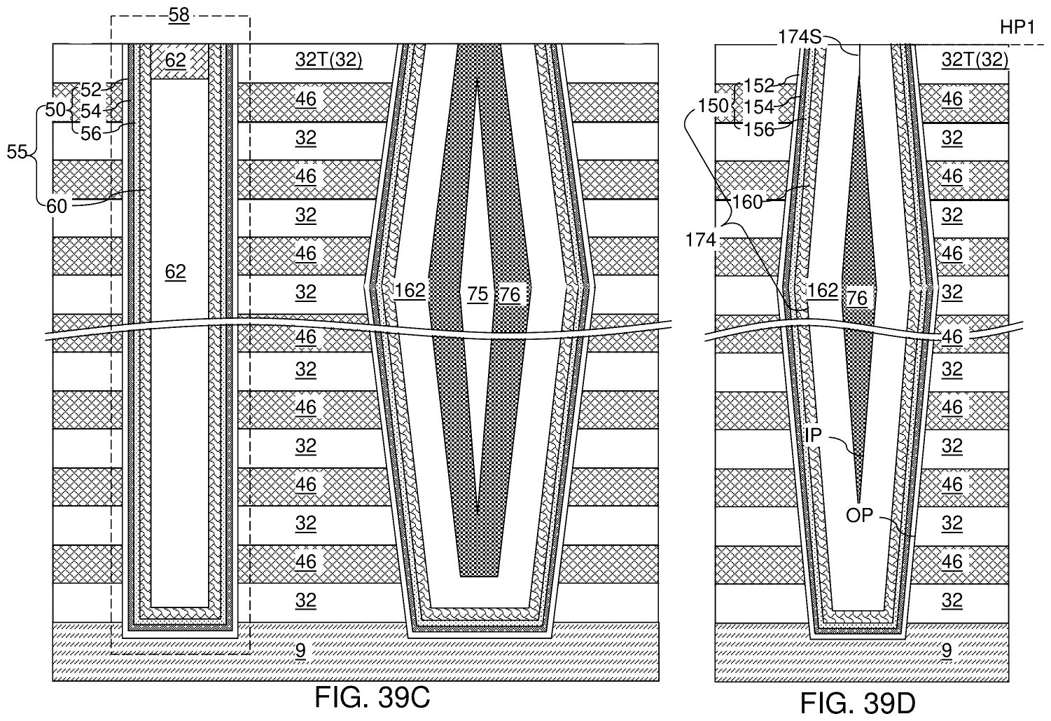

Referring to FIGS. 39A-39D, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel material layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. A memory opening fill structure 58 is formed within each memory opening 49. In one embodiment, the drain regions 63 may be omitted from the lateral isolation trench fill structures (174, 76). In another embodiment, dummy drain regions are formed in the lateral isolation trench fill structures (174, 76) at the same time as the drain regions 63 are formed in the memory opening fill structures.

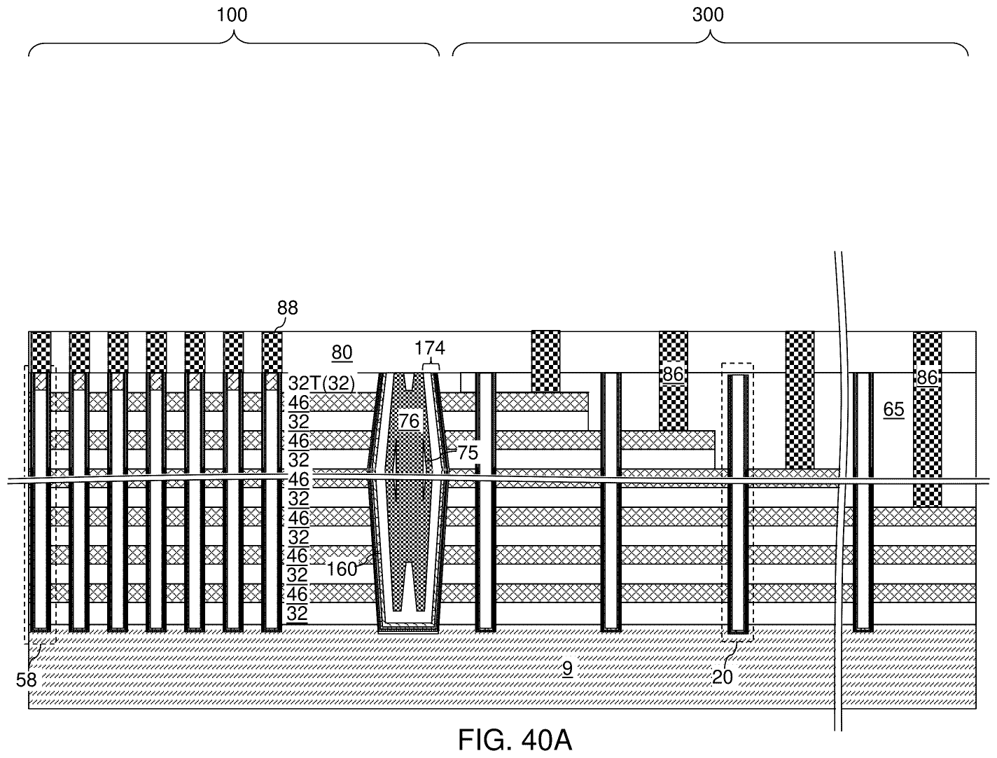

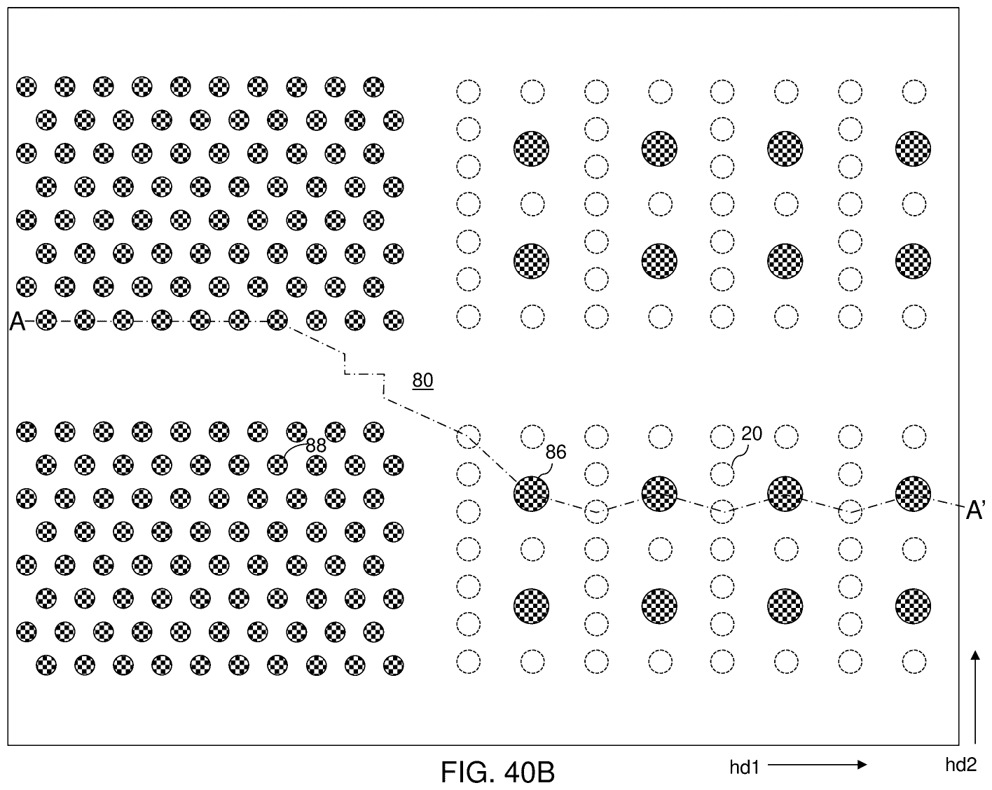

Referring to FIGS. 40A and 40B, a contact-level dielectric layer 80 can be formed above the alternating stacks (32, 46) and the stepped dielectric material portion 65. The processing steps described with reference to FIGS. 17A and 17B can be performed to form drain contact via structures 88 and layer contact via structures 86.

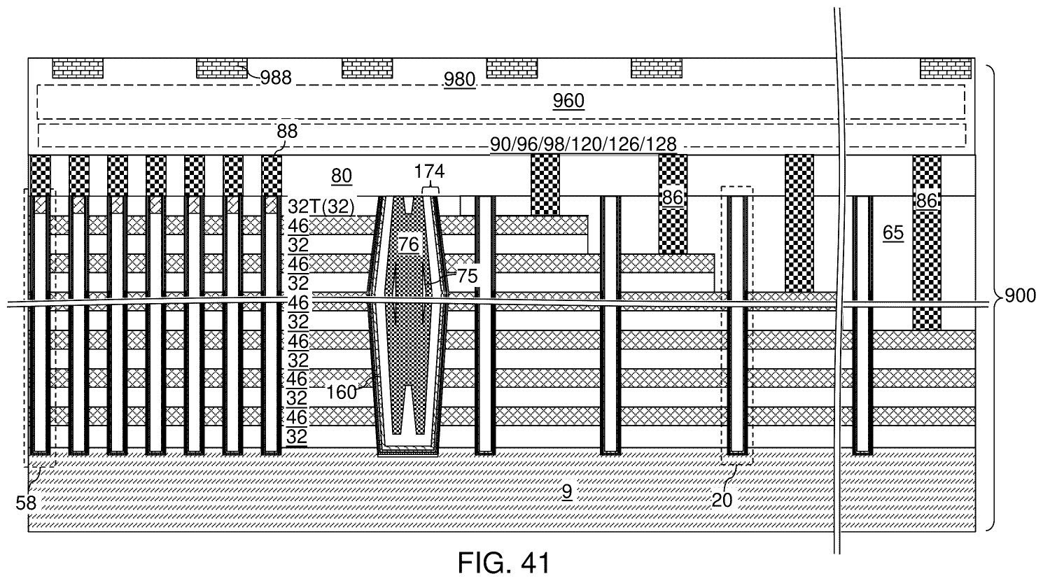

Referring to FIG. 41, the processing steps described with reference to FIGS. 18A, 18B, and 19 can be performed to form a connection-level dielectric layer 90, a bit-line-level dielectric layer 120, and additional dielectric material layers and additional metal interconnect structures embedded therein. The additional dielectric material layers that are formed above the contact-level dielectric layer 80 are herein referred to as memory-side dielectric material layers 960. The additional metal interconnect structures are collectively referred to as memory-side dielectric material layers 960. The memory-side dielectric material layers 960 comprise a bit-line-level dielectric material layer embedding the bit lines 128, which are a subset of the memory-side metal interconnect structures 980.

Metal bonding pads, which are herein referred to as memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the alternating stacks of insulating layers 32 and electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer among the memory-side dielectric material layers 960. The memory-side bonding pads 988 can be electrically connected to the memory-side metal interconnect structures 980.

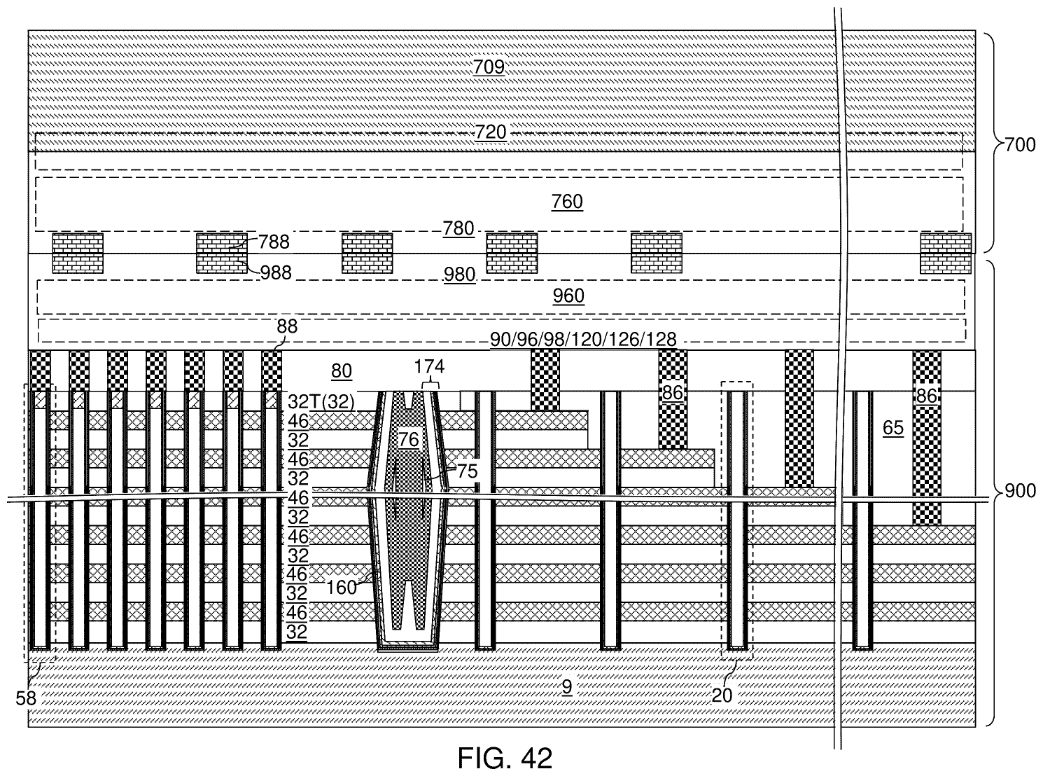

Referring to FIG. 42, the processing steps described with reference to FIGS. 20 and 21 can be performed to bond a logic die 700 to the memory die 900.

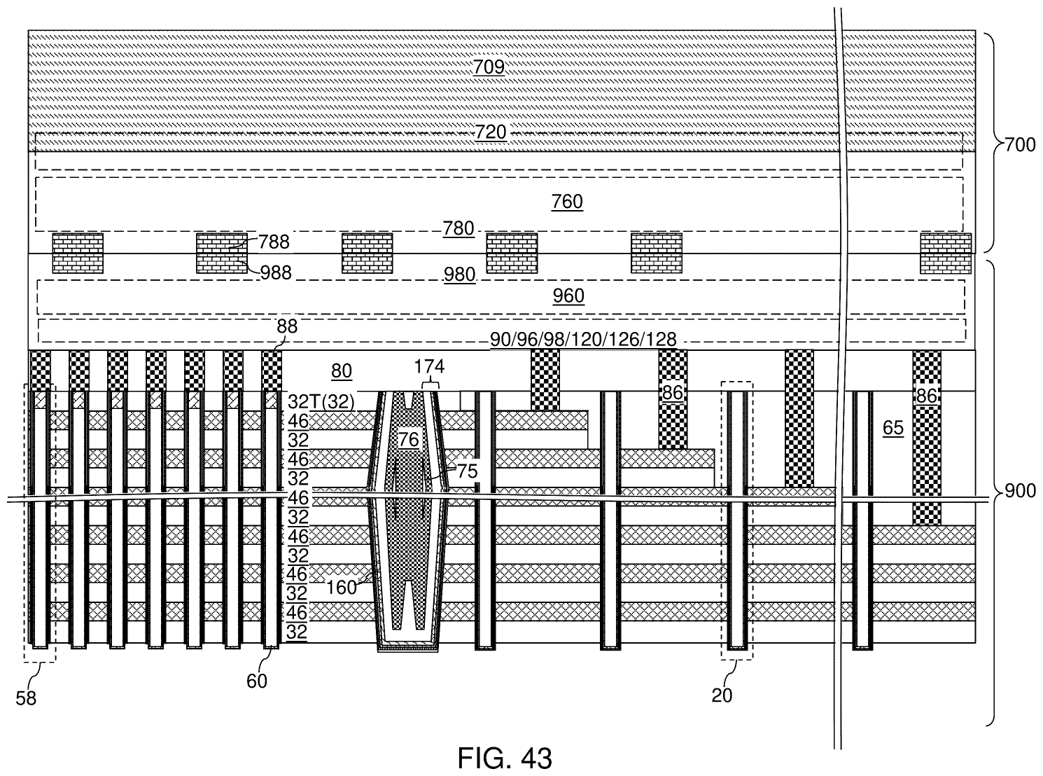

Referring to FIG. 43, the carrier substrate 9 can be removed, for example, by grinding, polishing, cleaving, an isotropic etch process, and/or an anisotropic etch process. If a polishing process such as a chemical mechanical polishing process is employed to remove the carrier substrate 9. If an etch process such as a wet etch process is employed to remove the carrier substrate 9 Bottom portions of the memory films 50 can be removed from each memory opening fill structure 58. Bottom surfaces of each vertical semiconductor channel 60 in the memory opening fill structures 58 can be physically exposed.

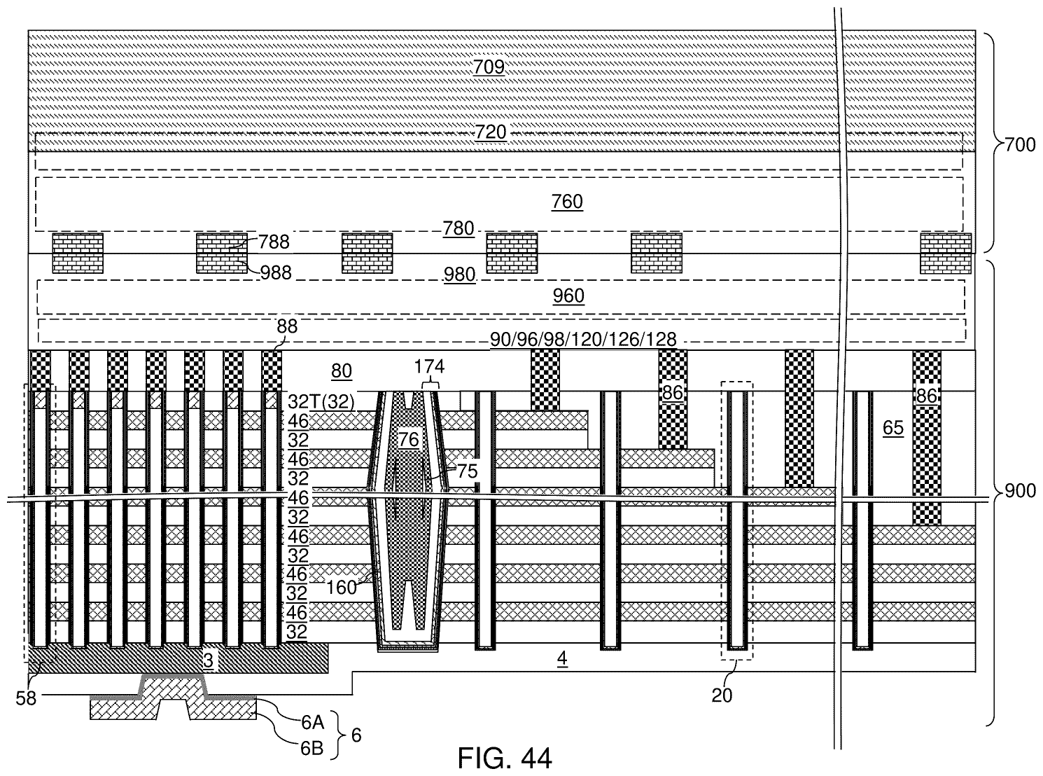

Referring to FIG. 44, a source layer 3 can be formed on the physically exposed bottom surfaces of the vertical semiconductor channels 60. The source layer 3 comprises a doped semiconductor material having a doping of the second conductivity type. A backside dielectric layer 4 can be formed over the source layer 3. At least one backside contact pad 6 can be formed through the backside dielectric layer 4. For example, the at least one backside contact pad 6 may comprise a source contact pad that is formed on the backside of the source layer 3. In one embodiment, each backside contact pad 6 may comprise a metallic barrier liner 6A and a metallic plate portion 6B.

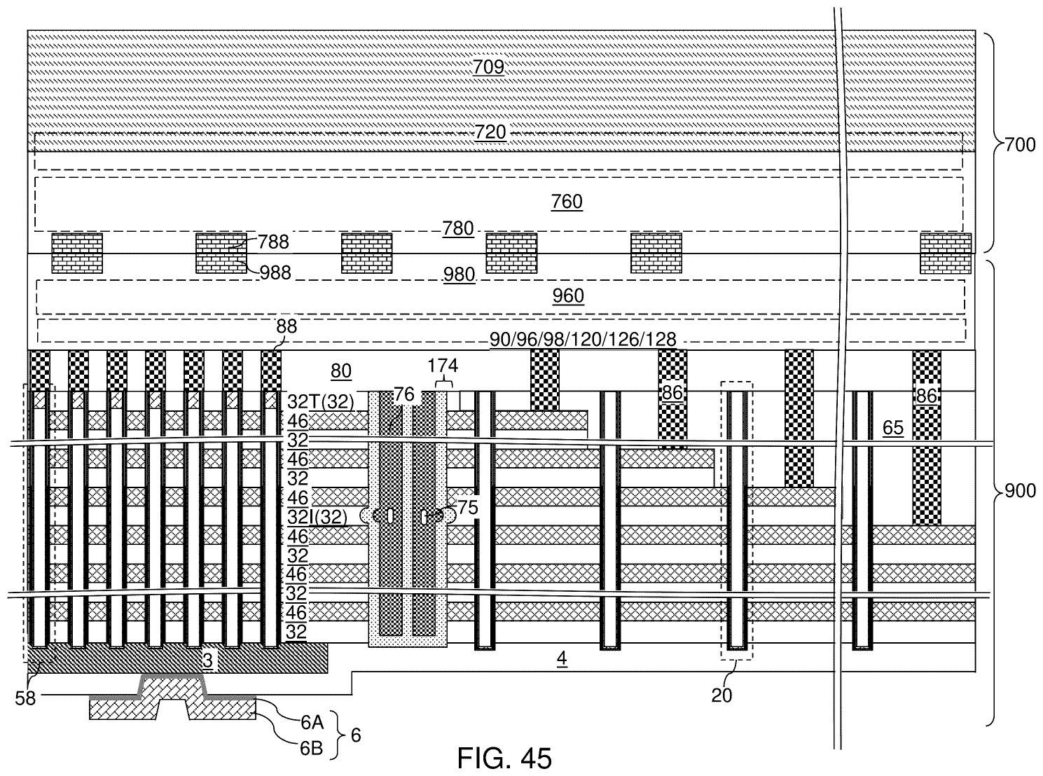

Referring to FIG. 45, an alternative configuration of the second exemplary structure is illustrated. The alternative configuration of the second exemplary structure can be derived from the second exemplary structure by employing multiple vertical alternating sequences of continuous insulating layers 32 and continuous sacrificial material layers 42 with at least one intervening insulating layer, which is herein referred to as at least one inter-tier insulating layer 32I. In this case, the maximum lateral extent of each lateral isolation trench 79 may be at the level of an inter-tier insulating layer 32I, which is one of the insulating layers 32 within an alternating stack (32, 46).

Referring to all drawings and according to various embodiments of the present disclosure, a three-dimensional memory device is provided, which comprises: a pair of alternating stacks (32, 46) of insulating layers 32 and electrically conductive layers 46, the pair of alternating stacks (32, 46) being laterally spaced from each other by a lateral isolation trench 79 that generally extends along a first horizontal direction hd1; memory openings 49 vertically extending through a respective one of the pair of alternating stacks (32, 46); memory opening fill structures 58 located in a respective one of the memory openings 49 and comprising a respective vertical stack of memory elements located at levels of the electrically conductive layers 46; and a lateral isolation trench fill structure {(74, 174), 76} located in the lateral isolation trench 79 and comprising a peripheral spacer (74, 174) and a conductive fill structure 76. The lateral isolation trench fill structure has a width modulation at levels of both the insulating layers 32 and the electrically conductive layers 42 along a second horizontal direction hd2 that is perpendicular to the first horizontal direction hd1 as a function of a lateral distance along the first horizontal direction.

In one embodiment, a first vertical cross-sectional view of the lateral isolation trench fill structure {(74, 174), 76} in a first vertical plane that is perpendicular to the first horizontal direction hd1 comprises: an outer periphery OP of the peripheral spacer (74, 174) which comprises a horizontal top surface segment located in a first horizontal plane HP1; and an inner periphery IP of the peripheral spacer (74, 174) that is vertically spaced from and located entirely below the first horizontal plane HP1.

In one embodiment, the horizontal top surface segment of the outer periphery OP of the peripheral spacer (74, 174) is connected to the inner periphery IP of the peripheral spacer (74, 174) by a vertically-extending seam 74S at which two vertical surfaces of the peripheral spacer (74, 174) are in direct contact with each other. In one embodiment, the outer periphery OP of the peripheral spacer (74, 174) comprises a pair of tapered upper sidewall segments that are adjoined to a respective end of the horizontal top surface segment of the peripheral spacer (74, 174); and a lateral spacing between the pair of tapered upper sidewall segments decreases with a vertical distance from a second horizontal plane HP2 located below the first horizontal plane HP1. In one embodiment, the outer periphery OP of the peripheral spacer (74, 174) further comprises a pair of tapered lower sidewall segments that underlie the pair of tapered upper sidewall segments of the peripheral spacer (74, 174); and a lateral spacing between the pair of tapered lower sidewall segments decreases with the vertical distance from the second horizontal plane HP2.

In one embodiment, the inner periphery IP of the peripheral spacer (74, 174) has a maximum width at the second horizontal plane HP2 which is located below top surfaces of topmost layers within the pair of alternating stacks and above bottommost surfaces of bottommost layers within the pair of alternating stacks. In one embodiment, the conductive fill structure 76 fills an entire area within the inner periphery IP of the peripheral spacer (74, 174) in the first vertical cross-sectional view.

In one embodiment, the lateral isolation trench fill structure {(74, 174), 76} comprises a periodic laterally alternating sequence of neck regions 78N having a minimum width along the second horizontal direction and bulging regions 78B having a maximum width along the second horizontal direction. In one embodiment, the lateral isolation trench fill structure {(74, 174), 76} comprises a pair of laterally-undulating lengthwise sidewalls; and each of the pair of laterally-undulating lengthwise sidewalls comprises a set of horizontally-convex and vertically-tapered surface segments that are adjoined to each other at edges. In one embodiment, a top surface of the conductive fill structure 76 has a height variation along the first horizontal direction hd1; and a top surface of the lateral isolation trench fill structure {(74, 174), 76} comprises a plurality of discrete top surface segments of the conductive fill structure 76 that are laterally spaced apart from each other by intervening portions of a top surface of the peripheral spacer (74, 174).

In one embodiment, the peripheral spacer (74, 174) comprises N laterally-extending tunnels that laterally extend along the first horizontal direction hd1; N is an integer greater than 23; and the conductive fill structure 76 comprises N vertically-extending portions that are located in the N laterally-extending tunnels. In one embodiment, the conductive fill structure 76 is a single continuous structure, and further comprises (N+1) vertically-extending portions that are interlaced with the N laterally-extending portions along the first horizontal direction hd1.

In one embodiment, the conductive fill structure 76 comprises titanium or titanium nitride. In one embodiment, the peripheral spacer (74, 174) consists of at least one dielectric material. In one embodiment, the peripheral spacer (74, 174) comprises at least one dielectric material and at least one semiconductor material that is electrically isolated from the conductive fill structure 76.

In one embodiment, the memory device comprises a memory die 900 containing bonding pads 988 located over the pair of alternating stacks (32, 46); a logic die 700 containing a peripheral circuit 720 is bonded to the bonding pads 988; and a semiconductor source layer 3 is located below the pair of alternating stacks in contact with ends of the vertical semiconductor channels 60.

The various embodiments of the present disclosure can be employed to provide lateral isolation trench fill structures {(74, 174), 76} including the conductive fill structures 76. The conductive fill structures 76 may comprise dummy structures which are not used as source contacts or interconnects, and which are not electrically connected to the source layer of the memory device. In one embodiment, the conductive fill structures 76 comprise low stress materials, such as titanium or titanium nitride, which provide high flex strength, low substrate warpage and no fluorine degassing. Airgaps (i.e., voids) 75 in the conductive fill structures 76, if present, are formed as discrete voids, and the conductive fill structures 76 are formed as a single continuous structure without a void at each neck region 78N of the lateral isolation trench fill structures {(74, 174), 76}. Thus, the conductive fill structures 76 can provide enhanced mechanical strength to the three-dimensional memory device.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A three-dimensional memory device, comprising:
a pair of alternating stacks of insulating layers and electrically conductive layers, the pair of alternating stacks being laterally spaced from each other by a lateral isolation trench that generally extends along a first horizontal direction;
memory openings vertically extending through a respective one of the pair of alternating stacks;
memory opening fill structures located in a respective one of the memory openings and comprising a respective vertical semiconductor channel and a respective vertical stack of memory elements located at levels of the electrically conductive layers; and
a lateral isolation trench fill structure located in the lateral isolation trench and comprising a peripheral spacer and a conductive fill structure, wherein the lateral isolation trench fill structure has a width modulation at levels of both the insulating layers and the electrically conductive layers along a second horizontal direction that is perpendicular to the first horizontal direction as a function of a lateral distance along the first horizontal direction.

2. The three-dimensional memory device of claim 1, wherein a first vertical cross-sectional view of the lateral isolation trench fill structure in a first vertical plane that is perpendicular to the first horizontal direction comprises:
an outer periphery of the peripheral spacer which comprises a horizontal top surface segment located in a first horizontal plane; and
an inner periphery of the peripheral spacer that is vertically spaced from and located entirely below the first horizontal plane.

3. The three-dimensional memory device of claim 2, wherein:
the outer periphery of the peripheral spacer comprises a pair of tapered upper sidewall segments that are adjoined to a respective end of the horizontal top surface segment of the peripheral spacer; and
a lateral spacing between the pair of tapered upper sidewall segments decreases with a vertical distance from a second horizontal plane located below the first horizontal plane.

4. The three-dimensional memory device of claim 3, wherein:
the outer periphery of the peripheral spacer further comprises a pair of tapered lower sidewall segments that underlie the pair of tapered upper sidewall segments of the peripheral spacer; and
a lateral spacing between the pair of tapered lower sidewall segments decreases with the vertical distance from the second horizontal plane.

5. The three-dimensional memory device of claim 3, wherein:
the inner periphery of the peripheral spacer has a maximum width at the second horizontal plane which is located below top surfaces of topmost layers within the pair of alternating stacks and above bottommost surfaces of bottommost layers within the pair of alternating stacks; and
the conductive fill structure fills an entire area within the inner periphery of the peripheral spacer in the first vertical cross-sectional view.

6. The three-dimensional memory device of claim 2, wherein the horizontal top surface segment of the outer periphery of the peripheral spacer is connected to the inner periphery of the peripheral spacer by a vertically-extending seam at which two vertical surfaces of the peripheral spacer are in direct contact with each other.

7. The three-dimensional memory device of claim 1, further comprising:
bonding pads located over the pair of alternating stacks;
a logic die containing a peripheral circuit bonded to the bonding pads; and
a semiconductor source layer located below the pair of alternating stacks in contact with ends of the vertical semiconductor channels.

8. The three-dimensional memory device of claim 1, wherein the lateral isolation trench fill structure comprises a periodic laterally alternating sequence of neck regions having a minimum width along the second horizontal direction and bulging regions having a maximum width along the second horizontal direction.

9. The three-dimensional memory device of claim 1, wherein:
the lateral isolation trench fill structure comprises a pair of laterally-undulating lengthwise sidewalls; and
each of the pair of laterally-undulating lengthwise sidewalls comprises a set of horizontally-convex and vertically-tapered surface segments that are adjoined to each other at edges.

10. The three-dimensional memory device of claim 1, wherein:
a top surface of the conductive fill structure has a height variation along the first horizontal direction; and
a top surface of the lateral isolation trench fill structure comprises a plurality of discrete top surface segments of the conductive fill structure that are laterally spaced apart from each other by intervening portions of a top surface of the peripheral spacer.

11. The three-dimensional memory device of claim 1, wherein:
the peripheral spacer comprises N laterally-extending tunnels that laterally extend along the first horizontal direction;
N is an integer greater than 23; and
the conductive fill structure comprises N vertically-extending portions that are located in the N laterally-extending tunnels.

12. The three-dimensional memory device of claim 11, wherein the conductive fill structure is a single continuous structure that further comprises (N+1) vertically-extending portions that are interlaced with the N laterally-extending portions along the first horizontal direction.

13. The three-dimensional memory device of claim 1, wherein the conductive fill structure consists essentially of titanium or titanium nitride.

14. The three-dimensional memory device of claim 1, wherein the peripheral spacer comprises at least one dielectric material.

15. The three-dimensional memory device of claim 1, wherein the peripheral spacer comprises at least one dielectric material and at least one semiconductor material that is electrically isolated from the conductive fill structure.

16. A method of forming a three-dimensional memory device, comprising:
forming a vertically alternating sequence of continuous insulating layers and continuous sacrificial material layers over a substrate;
forming memory openings through the vertically alternating sequence;
forming memory opening fill structures in the memory openings, wherein each of the memory opening fill structures comprises a respective vertical semiconductor channel and a respective vertical stack of memory elements;
forming a lateral isolation trench through the vertically alternating sequence, wherein the lateral isolation trench has a width modulation at levels of both the insulating layers and the sacrificial material layers along a second horizontal direction that is perpendicular to a first horizontal direction as a function of a lateral distance along the first horizontal direction;
replacing remaining portions of the continuous sacrificial material layers with electrically conductive layers to form a pair of alternating stacks of insulating layers and electrically conductive layers on opposing sides of the lateral isolation trench; and
forming a lateral isolation trench fill structure in the lateral isolation trench, wherein the lateral isolation trench fill structure comprises a peripheral spacer and a conductive fill structure that is formed in the peripheral spacer.

17. The method of claim 16, wherein:
the peripheral spacer comprises N laterally-extending tunnels that laterally extend along the first horizontal direction, wherein N is an integer greater than 23; and
the conductive fill structure comprises N horizontally-extending portions that are located in the N laterally-extending tunnels, and (N+1) vertically extending portions that are adjoined to and interlaced with the N horizontally-extending portions.

18. The method of claim 16, further comprising:
removing the substrate and exposing ends of the vertical semiconductor channels; and
forming a source layer on the exposed ends of the vertical semiconductor channels.

19. The method of claim 16, wherein the forming the lateral isolation trench through the vertically alternating sequence comprises:
forming discrete openings through the vertically alternating sequence; and
expanding the discrete openings at levels of the insulating layers and the sacrificial material layers to form the lateral isolation trench.

20. The method of claim 16, wherein the memory opening fill structures and the peripheral spacer are formed by:
sequentially depositing a set of material layers that include a plurality of dielectric material layers, a semiconductor channel material layer, and a dielectric core material layer; and
removing horizontally extending portions of the set of material layers from above the vertically alternating sequence, wherein:
the memory opening fill structures comprise portions of the set of material layers that remain in the memory openings; and
the peripheral spacer comprises portions of the set of material layers that remain in the lateral isolation trench.
